(19) United States
(12) Patent Application Publication
(10) Pub. No.: US 2004/0235237 A1
(43) Pub. Date: Nov. 25, 2004

(54) Semiconductor device and method for manufacturing the same

(76) Inventors: Hiroaki Inoue, Tokyo (JP); Kenji Nakamura, Kanagawa (JP); Moriji Matsumoto, Kanagawa (JP)

Correspondence Address: WENDEROTH, LIND & PONACK, L.L.P., 2033 K STREET N. W., SUITE 800, WASHINGTON, DC, 20006-1021, US

(21) Appl. No.: 10/479,429

(22) PCT Filed: Jun. 7, 2002
(86) PCT No.: PCT/JP02/05648

(30) Foreign Application Priority Data
Jun. 11, 2001 (JP) 2001-176176

(51) Int. Cl. H01L 21/8238

(52) U.S. Cl. 438/232

(57) ABSTRACT

There is provided a semiconductor device having such a protective film that selectively covers the surface of embedded interconnects and can effectively prevent both of the oxidation and the thermal diffusion of the interconnects. A method for manufacturing such a semiconductor device is also provided. The semiconductor device includes: a semiconductor substrate having an embedded interconnect structure in which the embedded interconnects have an exposed surface; and a protective film composed of a multi-layer laminated film formed selectively on the exposed surface of interconnects. The multi-layer laminated film preferably includes an oxidation-preventing layer, composed of e.g. a Ni or Ni alloy layer, for preventing oxidation of the interconnects, and a thermal diffusion-preventing layer, composed of e.g. a Co or Co alloy layer, for preventing thermal diffusion of the interconnects.

### TECHNICAL FIELD

This invention relates to a semiconductor device and a method for manufacturing the same, and more particularly to a semiconductor device having an embedded interconnect structure in which an electric conductor, such as copper or silver, is embedded in fine recesses for interconnects formed in the surface of a semiconductor substrate, and having a protective film formed on the surface of the interconnects to protect the interconnects, and to a method for manufacturing such a semiconductor device.

### BACKGROUND ART

As a process for forming interconnects in a semiconductor device, the so-called “damascene process”, which comprises filling trenches for interconnects and contact holes with a metal (electric conductor), is coming into practical use. According to this process, aluminum or more recently a metal such as silver or copper, is embedded into trenches for interconnects and contact holes previously formed in the interlevel dielectric of a semiconductor substrate. Thereafter, an extra metal is removed by chemical mechanical polishing (CMP) so as to flatten the surface of the substrate.

In the case of interconnects formed by such a process, the embedded interconnects have an exposed surface after the flattening processing. When an additional embedded interconnect structure is formed on such an exposed surface of the interconnects of a semiconductor substrate, the following problems may be encountered. For example, during the formation of new SiO₂ interlevel dielectric, the exposed surface of the pre-formed interconnects is likely to be oxidized. Further, upon etching of the SiO₂ layer for the formation of via holes, the pre-formed interconnects exposed at the bottoms of via holes can be contaminated with an etchant, a peeled resist, etc.

In order to avoid such problems, it has conventionally been practiced to form a protective film of SiN or the like not only on the interconnect region of a semiconductor substrate where the interconnects are exposed, but on the entire surface of the substrate, thereby preventing the contamination of the exposed interconnects with an etchant, etc.

However, the provision of a protective film of SiN or the like on the entire surface of a semiconductor substrate, in a semiconductor device having an embedded interconnect structure, increases the dielectric constant of the interlevel dielectric, thus inducing delayed interconnection even when a low-resistance material, such as copper or silver, is employed as an interconnect material, whereby the performance of the electric device may be impaired.

In view of this, it has been proposed to protect interconnects by selectively covering the surface of the interconnects with a Co (cobalt) or Co alloy, or a Ni (nickel) or Ni alloy layer, which has a good adhesion to an interconnect material, such as copper or silver, and has a low resistivity (ρ), and which can be formed e.g. by electroless plating.

A Co or Co alloy layer, when formed selectively on the surface of embedded interconnects by electroless plating in order to protect the interconnects, can effectively prevent thermal diffusion of the interconnects; however, such a cobalt-based layer cannot effectively prevent oxidation of the interconnects. In contrast thereto, a Ni or Ni alloy layer, when formed selectively on the surface of embedded interconnects to protect the interconnects, can effectively prevent oxidation of the interconnects, but cannot effectively prevent thermal diffusion of the interconnects. The provision of a Co or Co alloy layer or of a Ni or Ni alloy selectively on the surface of interconnects for the purpose of protecting the interconnects, thus involves the drawback that it fails to effectively prevent both of the oxidation and the thermal diffusion of the interconnects.

### DISCLOSURE OF INVENTION

The present invention has been made in view of the above situation in the related art. It is, therefore an object of the present invention to provide a semiconductor device having such a protective film that selectively covers the surface of embedded interconnects and can effectively prevent both of the oxidation and the thermal diffusion of the interconnects, and to provide a method for manufacturing such the semiconductor device.

In order to achieve the above object, the present invention provides a semiconductor device, comprising: a semiconductor substrate having an interconnect structure in a surface of the semiconductor substrate; an embedded interconnect embedded in the interconnect structure and having an exposed surface; a first protective layer formed selectively on the exposed surface of the interconnect; and a second protective layer formed on a surface of the first protective layer, wherein a material of the second protective layer being different from a material of the first protective layer.

The first and second protective layers having various physical properties, when formed as protective layers selectively on the exposed interconnect, will perform a combination of various protective functions, each layer performing its own function.

The first protective layer may be a thermal diffusion-preventing layer for preventing thermal diffusion of the interconnect, and the second protective layer may be an oxidation-preventing layer for preventing oxidation of the interconnect.

The combination of the oxidation-preventing layer and the thermal diffusion-preventing layer allows the laminated protective film to effectively prevent both of the oxidation and the thermal diffusion of the interconnect.

It is preferred that the oxidation-preventing layer be laminated on the surface of the thermal diffusion-preventing layer. By thus covering the surface of the thermal diffusion-preventing layer with the oxidation-preventing layer, oxidation of the interconnect, e.g. upon deposition of an insulating film (oxide film) in an oxidizing atmosphere for the formation of a multi-layer interconnect structure of a semiconductor device, can be prevented without any lowering of the oxidation-preventing effect.

In a preferred embodiment, the thermal diffusion-preventing layer comprises a Co or Co alloy layer, and the oxidation-preventing layer comprises a Ni or Ni alloy layer. By making the thermal diffusion-preventing layer of a Co or Co alloy that has excellent thermal diffusion-preventing properties and the oxidation-preventing layer of a Ni or a Ni alloy that has excellent oxidation-preventing properties, the laminated protective film can effectively prevent both of the oxidation and the thermal diffusion of the interconnect.

The present invention further provides a method for manufacturing a semiconductor device, comprising: providing a semiconductor substrate having an interconnect structure in a surface of the semiconductor substrate; filling the interconnect structure with an electric conductor to form an embedded interconnect having an exposed surface; forming a first protective layer selectively on the exposed surface of the interconnect; and forming a second protective layer on a surface of the first protective layer, wherein a material of the second protective layer is different from a material of the first protective layer.

Each of the protective layers may be formed by electroless plating. Electroless plating as carried out by using e.g. a plating solution containing an alkylamine borane as a reducing agent, is known to effect plating selectively on copper or silver. Selective plating only on the interconnect region of a semiconductor substrate is thus possible.

In a preferred embodiment, the first protective layer is a thermal diffusion-preventing layer composed of a Co or Co alloy layer, and the second protective layer is an oxidation-preventing layer composed of a Ni or Ni alloy layer.

The present invention further provides a method for manufacturing a semiconductor device, comprising: providing a semiconductor substrate having in its, surface a recess for interconnect; embedding an electric conductor into the recess of a surface of the substrate; flattening a surface of the substrate by chemical mechanical polishing, thereby forming an embedded interconnect having an exposed surface; forming a first protective layer selectively on the exposed surface of the interconnect by electroless plating; and forming a second protective layer selectively on a surface of the first protective layer by electroless plating.

The present invention provides an apparatus for manufacturing a semiconductor device, comprising: a first electroless plating device for forming a first protective layer selectively on a exposed surface of an embedded interconnect formed in a semiconductor substrate; and a second electroless plating device for forming a second protective layer selectively on a surface of the first layer.

The above and other objects, features, and advantages of the present invention will be apparent from the following description when taken in conjunction with the accompanying drawings which illustrates preferred embodiments of the present invention by way of example.

### BRIEF DESCRIPTION OF DRAWINGS

FIGS. 1A through 1C are diagrams illustrating, in sequence of process steps (up to a CMP step), an example of the formation of copper interconnects in a semiconductor device;

FIGS. 2A through 2C are diagrams illustrating, in sequence of process steps (after a CMP step), an example of the formation of copper interconnects in a semiconductor device according to the present invention;

FIG. 3 is a block diagram illustrating the process steps of electroless plating according to the present invention;

FIG. 4 is a schematic view of an example of an electroless plating device;

FIG. 5 is a schematic view of another example of an electroless plating device;

FIG. 6 is a plan view of an example of a substrate plating apparatus;

FIG. 7 is a schematic view showing airflow in the substrate plating apparatus shown in FIG. 6;

FIG. 8 is a cross-sectional view showing airflows among areas in the substrate plating apparatus shown in FIG. 6;

FIG. 9 is a perspective view of the substrate plating apparatus shown in FIG. 6, which is placed in a clean room;

FIG. 10 is a plan view of an example of an apparatus for manufacturing a semiconductor device;

FIG. 11 is a plan view of another example of an apparatus for manufacturing a semiconductor device;

FIG. 12 is a plan view of still another example of an apparatus for manufacturing a semiconductor device;

FIG. 13 is a view showing a plan constitution example of an apparatus for manufacturing a semiconductor device;

FIG. 14 is a view showing another plan constitution example of an apparatus for manufacturing a semiconductor device;

FIG. 15 is a view showing still another plan constitution example of an apparatus for manufacturing a semiconductor device;

FIG. 16 is a view showing still another plan constitution example of an apparatus for manufacturing a semiconductor device;

FIG. 17 is a view showing still another plan constitution example of an apparatus for manufacturing a semiconductor device;

FIG. 18 is a view showing still another plan constitution example of an apparatus for manufacturing a semiconductor device;

FIG. 19 is a view showing a flow of the respective steps in the apparatus for manufacturing a semiconductor device illustrated in FIG. 18;

FIG. 20 is a view showing a schematic constitution example of a bevel and backside cleaning unit;

FIG. 21 is a vertical sectional view of an example of an annealing unit; and

FIG. 22 is a transverse sectional view of the annealing unit.

### BEST MODE FOR CARRYING OUT THE INVENTION

Preferred embodiments of the present invention will now be described with reference to the drawings.

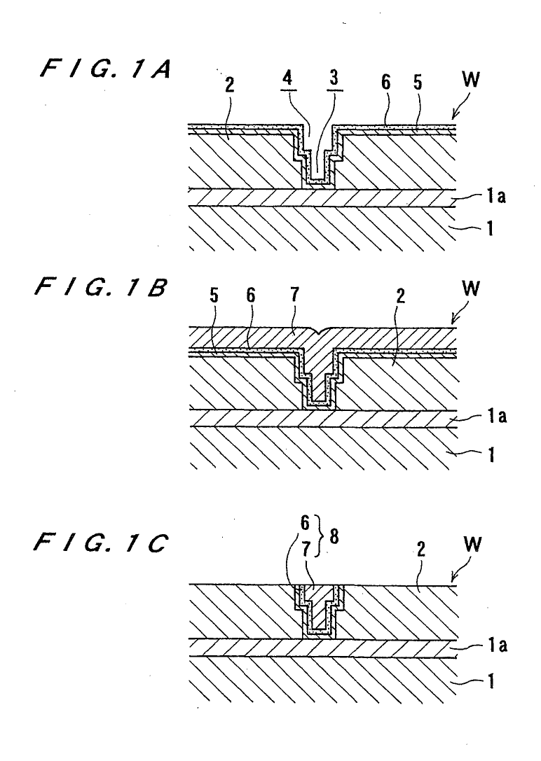

FIGS. 1A through 1C illustrate, in sequence of process steps, an example of the formation of copper interconnects in a semiconductor device. As shown in FIG. 1A, an insulating film 2 of e.g. SiO₂ is deposited on a conductive layer 1a in which semiconductor devices are provided, which is formed on a semiconductor base 1. Contact holes 3 and trenches 4 for interconnects are formed in the insulating film 2 by the lithography/etching technique. Thereafter, a barrier layer 5 of TaN or the like is formed on the entire surface, and a copper seed layer 6 as an electric supply layer for electroplating is formed on the barrier layer 5, for example, by sputtering.

Thereafter, as shown in FIG. 1B, copper plating is carried out onto the surface of the semiconductor substrate W to fill the contact holes 3 and the trenches 4 with copper and, at the same time, deposit a copper layer 7 on the insulating film 2. Thereafter, the copper layer 7 and the barrier layer 5 on the insulating film 2 are removed by chemical mechanical polishing (CMP) so as to make the surface of the copper layer 7 filled in the contact holes 3 and the trenches 4 for interconnects and the surface of the insulating film 2 lie substantially on the same plane. Interconnects 8 composed of the copper seed layer 6 and the copper layer 7, as shown in FIG. 1C, are thus formed in the insulating layer 2.

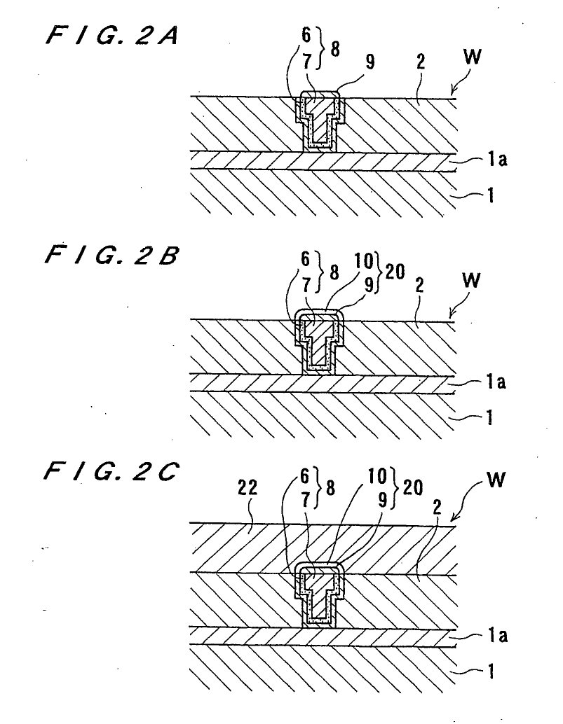

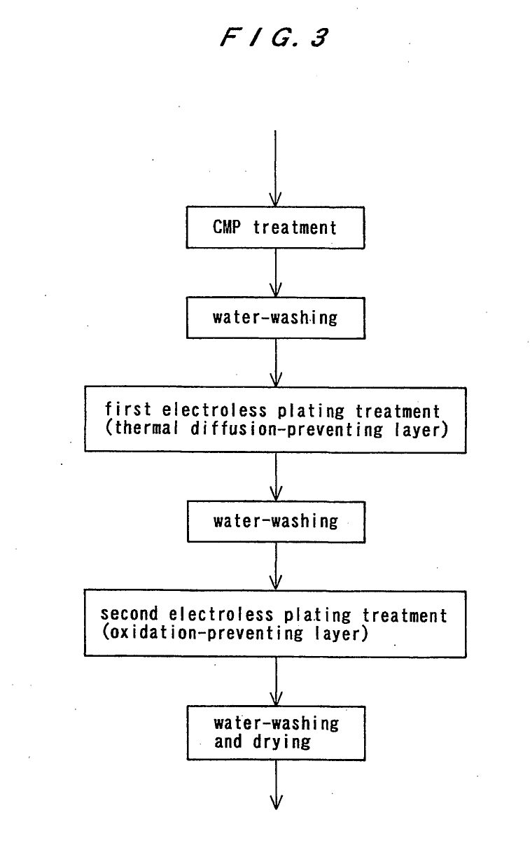

According to the semiconductor device of the present invention, as shown in FIGS. 2A through 2C, the exposed surface of the interconnects 8 which have been formed in the substrate W as described above, is selectively covered and protected with a protective film 20 composed of a multi-layer laminated film consisting of e.g. a thermal diffusion-preventing layer 9 and an oxidation-preventing layer 10. Further, an insulating film 22 of SiO₂, SiOF or the like is superimposed on the surface of the substrate W to form a multi-layer interconnect structure. FIG. 3 illustrates an example of process steps to be carried out for forming the two-layer protective film 20. According to this example, the substrate W after a CMP treatment is water-washed. Thereafter, a first electroless plating is carried out onto the surface of the substrate W to form the thermal diffusion-preventing layer 9, composed of e.g. a Co alloy layer, selectively on the exposed surface of interconnects 8, as shown in FIG. 2A. After water-washing the substrate, a second electroless plating is carried out to form the oxidation-preventing layer 10, composed of e.g. a Ni alloy layer, selectively on the surface of the thermal diffusion-preventing layer 9, as shown in FIG. 2B. After water-washing and drying the substrate, the insulating film 22 is deposited on the substrate W, as shown FIG. 2C.

By thus selectively covering the exposed surface of interconnects 8 and protecting the interconnects with the protective film 20 composed of the multi-layer laminated film consisting of the thermal diffusion-preventing layer 9, composed of e.g. a Co alloy layer, which can effectively prevent thermal diffusion of the interconnects, and the oxidation-preventing layer 10, composed of e.g. a Ni alloy layer, which can effectively prevent oxidation of the interconnects, both of the oxidation and the thermal diffusion of the interconnects can be effectively prevented. In this regard, protection of the interconnects only with a Co or Co alloy layer could not effectively prevent oxidation of the interconnects; protection of the interconnects only with a Ni or Ni alloy layer could not effectively prevent thermal diffusion of the interconnects. These drawbacks can be obviated by the combination of the two layers.

Further, by laminating the oxidation-preventing layer 10 on the surface of the thermal diffusion-preventing layer 9, oxidation of the interconnects, e.g. upon deposition of the insulating film 22 in an oxidizing atmosphere for the formation of a multi-layer interconnect structure of a semiconductor device, can be prevented without any lowering of the oxidation-preventing effect.

The thermal diffusion-preventing layer 9 may be composed of a Co—W—B alloy. Such a thermal diffusion-preventing layer (Co—W—B alloy layer) 9 can be formed by using a electroless plating solution containing cobalt ions, a complexing agent, a pH buffer, a pH adjusting agent, an alkylamine borane as a reducing agent, and a tungsten-containing compound, and by immersing the surface of the substrate W in the plating solution. The thermal diffusion-preventing layer 9 may be formed by ejecting a plating solution toward the surface of the substrate from a ejecting nozzle or by holding a plating solution on the surface of the substrate held upward by a substrate holder.

If desired, the plating solution may further contain at least one of a stabilizer selected from one or more kinds of heavy metal compounds and sulfur compounds, and a surfactant. Further, the plating solution is adjusted within the pH range of preferably 5-14, more preferably 6-10, by using a pH adjusting agent such as ammonia water or ammonium hydroxide. The temperature of the plating solution is generally in the range of 30-90° C., preferably 40-80° C.

The cobalt ions contained in the plating solution may be supplied from a cobalt salt, for example, cobalt sulfate, cobalt chloride or cobalt acetate. The amount of the cobalt ions is generally in the range of 0.001-1.0 mol/L, preferably 0.01-0.3 mol/L.

Specific examples of the complexing agent may include carboxylic acids, such as acetic acid, or their salts; oxycarboxylic acids, such as tartaric acid and citric acid, and their salts; and aminocarboxylic acids, such as glycine, and their salts. These comounds may be used either singly or as a mixture of two or more. The total amount of the complexing agent is generally 0.001-1.5 mol/L, preferably 0.01-1.0 mol/L.

Specific examples of the pH buffer may include ammonium sulfate, ammonium chloride and boric acid. The pH buffer can be used generally in an amount of 0.01-1.5 mol/L, preferably 0.1-1.0 mol/L.

Specific examples of the pH adjusting may include ammonia water and tetramethylammonium hydroxide (TMAH). By using the pH adjusting agent, the pH of the plating solution is adjusted generally within the range of 5-14, preferably 6-10.

The alkylamine borane as a reducing agent may specifically be dimethyl amine borane(DMAB) or diethyl amine borane. The reducing agent is used generally in an amount of 0.01-1.0 mol/L, preferably 0.01-0.5 mol/L.

Examples of the tungsten-containing compound may include tangstic acid or its salts, and heteropoly acids, such as tangstophosphoric acid (e.g. H₃(PW₁₂P₄₀) .nH₂O), and their salts. The tungsten-containing compound is used generally in an amount of 0.001-1.0 mol/L, preferably 0.01-0.1 mol/L.

Besides the above-described compounds, other known additives may be added to the plating solution. Examples of usable additives include a plating bath stabilizer, which may be a heavy metal compound such as a lead compound, a sulfur compound such as a thiocyanate, or a mixture thereof, and a surfactant of an anionic, cationic or nonionic type.

The use of the sodium-free alkylamine borane as a reducing agent, which allows an oxidizing electric current to flow to copper, a copper alloy, silver or a silver alloy, makes it possible to carry out electroless plating by directly immersing the surface of the substrate W in the plating solution without a pretreatment of imparting a palladium catalyst to the interconnects.

Though the case of using a Co—W—B alloy for the thermal diffusion-preventing layer 9 has been described, Co as a single substance, Co—W—P alloy, Co—P alloy, Co—B alloy, or other Co alloys may also be used.

The oxidation-preventing layer 10 may be composed of a Ni—B alloy. Such an oxidation-preventing layer (Ni—B alloy layer) 10 can be formed by using an electroless plating solution which contains nickel ions, a complexing agent for nickel ions, an alkylamine borane or a borohydride compound as a reducing agent for nickel ions, and ammonia ions, and which is adjusted within a pH range of e.g. 8-12, and by immersing the surface of the substrate W in the plating solution. The oxidation-preventing layer 10 may be formed by ejecting a plating solution toward the surface of the substrate from a ejecting nozzle or by holding a plating solution on the surface of the substrate held upward by a substrate holder. The temperature of the plating solution is generally in the range of 50-90° C., preferably 55-75° C.

The complexing agent for nickel ions may specifically be malic acid, glycine, etc, and the borohydride compound may be e.g. NaBH₄.

As in the case of the above-described plating solution for forming the Co—W—B alloy layer, the use of an alkylamine borane as a reducing agent in the nickel-containing plating solution makes it possible to carry out electroless plating by directly immersing the surface of the substrate W in the plating solution without carrying out a palladium catalyst-imparting pretreatment. Further, the use of the same reducing agent, alkylamine borane, in the two plating solutions enables the two electroless plating treatments to be carried out successively.

Though the case of using a Ni—B alloy for the oxidation-preventing layer 10 has been described, Ni as a single substance, Ni—P alloy, Ni—W—P alloy, or other Ni alloys may also be used.

Further, though the case of using copper as an interconnect material has been described, it is also possible to use a copper alloy, silver or a silver alloy.

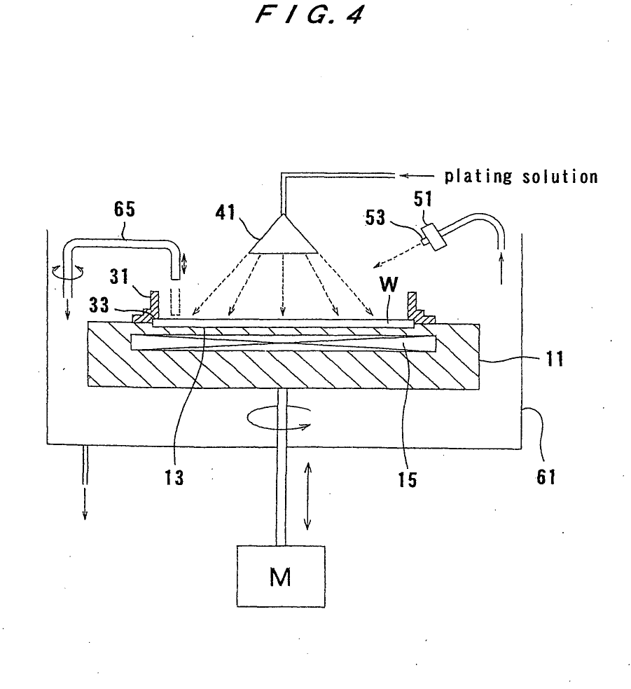

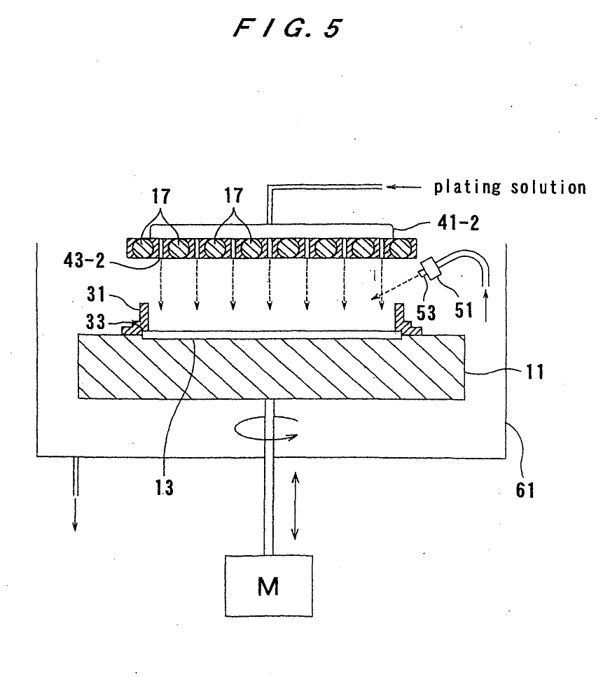

FIG. 4 is a schematic constitution drawing of the electroless plating device. As shown in FIG. 4, this electroless plating device comprises holding means 11 for holding a semiconductor substrate W to be plated on its upper surface, a dam member 31 for contacting a peripheral edge portion of a surface to be plated (upper surface) of the semiconductor substrate W held by the holding means 11 to seal the peripheral edge portion of the semiconductor substrate W, and a shower head 41 for supplying a plating solution to the surface, to be plated, of the semiconductor substrate W having the peripheral edge portion sealed with the dam member 31. The electroless plating device further comprises cleaning liquid supply means 51 disposed near an upper outer periphery of the holding means 11 for supplying a cleaning liquid to the surface, to be plated, of the semiconductor substrate W, a recovery vessel 61 for recovering a cleaning liquid or the like (plating waste solution) discharged, a plating solution recovery nozzle 65 for sucking in and recovering the plating solution held on the semiconductor substrate W, and a motor M for rotationally driving the holding means 11.

The holding means 11 has a substrate placing portion 13 on its upper surface for placing and holding the semiconductor substrate W. The substrate placing portion 13 is adapted to place and fix the semiconductor substrate W. Specifically, the substrate placing portion 13 has a vacuum attracting mechanism (not shown) for attracting the semiconductor substrate W to a backside thereof by vacuum suction. A backside heater (heating means) 15, which is planar and heats the surface, to be plated, of the semiconductor substrate W from underside to keep it warm, is installed on the backside of the substrate placing portion 13. The backside heater 15 is composed of, for example, a rubber heater. This holding means 11 is adapted to be rotated by the motor M and is movable vertically by raising and lowering means (not shown).

The dam member 31 is cylindrical, has a seal portion 33 provided in a lower portion thereof for sealing the outer peripheral edge of the semiconductor substrate W, and is installed so as not to move vertically from the illustrated position.

The shower head 41 is of a structure having many nozzles provided at the front end for scattering the supplied plating solution in a shower form and supplying it substantially uniformly to the surface, to be plated, of the semiconductor substrate W. The cleaning liquid supply means 51 has a structure for ejecting a cleaning liquid from a nozzle 53.

The plating solution recovery nozzle 65 is adapted to be movable upward and downward and swingable, and the front end of the plating solution recovery nozzle 65 is adapted to be lowered inwardly of the dam member 31 located on the upper surface peripheral edge portion of the semiconductor substrate W and to suck in the plating solution on the semiconductor substrate W.

Next, the operation of the electroless plating device will be described. First, the holding means 11 is lowered from the illustrated state to provide a gap of a predetermined dimension between the holding means 11 and the dam member 31, and the semiconductor substrate W is placed on and fixed to the substrate placing portion 13. An 8-inch substrate, for example, is used as the semiconductor substrate W.

Then, the holding means 11 is raised to bring its upper surface into contact with the lower surface of the dam member 31 as illustrated in FIG. 4, and the outer periphery of the semiconductor substrate W is sealed with the seal portion 33 of the dam member 31. At this time, the surface of the semiconductor substrate W is in an open state.

Then, the semiconductor substrate W itself is directly heated by the backside heater 15. Then, the plating solution is ejected from the shower head 41 to pour the plating solution over substantially the entire surface of the semiconductor substrate W. Since the surface of the semiconductor substrate W is surrounded by the dame member 31, the poured plating solution is all held on the surface of the semiconductor substrate W. The amount of the supplied plating solution may be a small amount, which will become a 1 mm thickness (about 30 ml) on the surface of the semiconductor substrate W. The depth of the plating solution held on the surface to be plated may be 10 mm or less, and may be even 1 mm as in this embodiment. If a small amount of the supplied plating solution is sufficient, the heating apparatus for heating the plating solution may be of a small size.

If the semiconductor substrate W itself is adapted to be heated as described above, the temperature of the plating solution requiring a great electric power consumption for heating need not be raised so high. This is preferred, because the electric power consumption can be decreased, and a change in the property of the plating solution can be prevented. The electric power consumption for heating of the semiconductor substrate W itself may be small, and the amount of the plating solution stored on the semiconductor substrate W is also small. Thus, heat retention of the semiconductor substrate W by the backside heater 15 can be performed easily, and the capacity of the backside heater 15 may be small, and the apparatus can be made compact. If means for directly cooling the semiconductor substrate W itself is used, switching between heating and cooling may be performed during plating to change the plating conditions. Since the plating solution held on the semiconductor substrate is in a small amount, temperature control can be performed with good sensitivity.

The semiconductor substrate W is instantaneously rotated by the motor M to perform uniform liquid wetting of the surface to be plated, and then plating of the surface to be plated is performed in such a state that the semiconductor substrate W is in a stationary state. Specifically, the semiconductor substrate W is rotated at 100 rpm or less for only 1 second to uniformly wet the surface, to be plated, of the semiconductor substrate W with the plating solution. Then, the semiconductor substrate W is kept stationary, and electroless plating is performed for 1 minute. The instantaneous rotating time is 10 seconds or less at the longest.

After completion of the plating treatment, the front end of the plating solution recovery nozzle 65 is lowered to an area near the inside of the dam member 31 on the peripheral edge portion of the semiconductor substrate W to suck in the plating solution on the semiconductor substrate W. At this time, if the semiconductor substrate W is rotated at a rotational speed of, for example, 100 rpm or less, the plating solution remaining on the semiconductor substrate W can be gathered in the portion of the dam member 31 on the peripheral edge portion of the semiconductor substrate W under centrifugal force, so that recovery of the plating solution can be performed with a good efficiency and a high recovery rate. The holding means 11 is lowered to separate the semiconductor substrate W from the dam member 31. The semiconductor substrate W is started to be rotated, and the cleaning liquid (ultra-pure water) is jetted at the plated surface of the semiconductor substrate W from the nozzle 53 of the cleaning liquid supply means 51 to cool the plated surface, and simultaneously perform dilution and cleaning, thereby stopping the electroless plating reaction. At this time, the cleaning liquid jetted from the nozzle 53 may be supplied to the dam member 31 to perform cleaning of the dam member 31 at the same time. The plating waste solution at this time is recovered into the recovery vessel 61 and discarded.

The plating solution once used is not reused, but thrown away. As stated above, the amount of the plating solution used in this electroless plating device can be made very small, compared with that in the prior art. Thus, the amount of the plating solution which is discarded is small, even without reuse. In some cases, the plating solution recovery nozzle 65 may not be installed, and the plating solution which has been used may be recovered as a plating waste solution into the recovery vessel 61, together with the cleaning liquid.

Then, the semiconductor substrate W is rotated at a high speed by the motor M for spin-drying, and then the semiconductor substrate W is removed from the holding means 11.

FIG. 5 is a schematic constitution drawing of another electroless plating device. The electroless plating device of FIG. 5 is different from the electroless plating device of FIG. 4 in that instead of providing the backside heater 15 in the holding means 11, lamp heaters 17 are disposed above the holding means 11, and the lamp heaters 17 and a shower head 41-2 are integrated. For example, a plurality of ring-shaped lamp heaters 17 having different radii are provided concentrically, and many nozzles 43-2 of the shower head 41-2 are open in a ring form from the gaps between the lamp heaters. 17. The lamp heaters 17 may be composed of a single spiral lamp heater, or may be composed of other lamp heaters of various structures and arrangements.

Even with this constitution, the plating solution can be supplied from each nozzle 43-2 to the surface, to be plated, of the semiconductor substrate W substantially uniformly in a shower form. Further, heating and heat retention of the semiconductor substrate W can be performed by the lamp heaters 17 directly uniformly. The lamp heaters 17 heat not only the semiconductor substrate W and the plating solution, but also ambient air, thus exhibiting a heat retention effect on the semiconductor substrate W.

Direct heating of the semiconductor substrate W by the lamp heaters 17 requires the lamp heaters 17 with relatively large electric power consumption. In place of such lamp heaters 17, lamp heaters 17 with a relatively small electric power consumption and the backside heater 15 shown in FIG. 4 may be used in combination to heat the semiconductor substrate W mainly with the backside heater 15 and to perform heat retention of the plating solution and ambient air mainly by the lamp heaters 17. In the same manner, means for directly or indirectly cooling the semiconductor substrate w may be provided to perform temperature control.

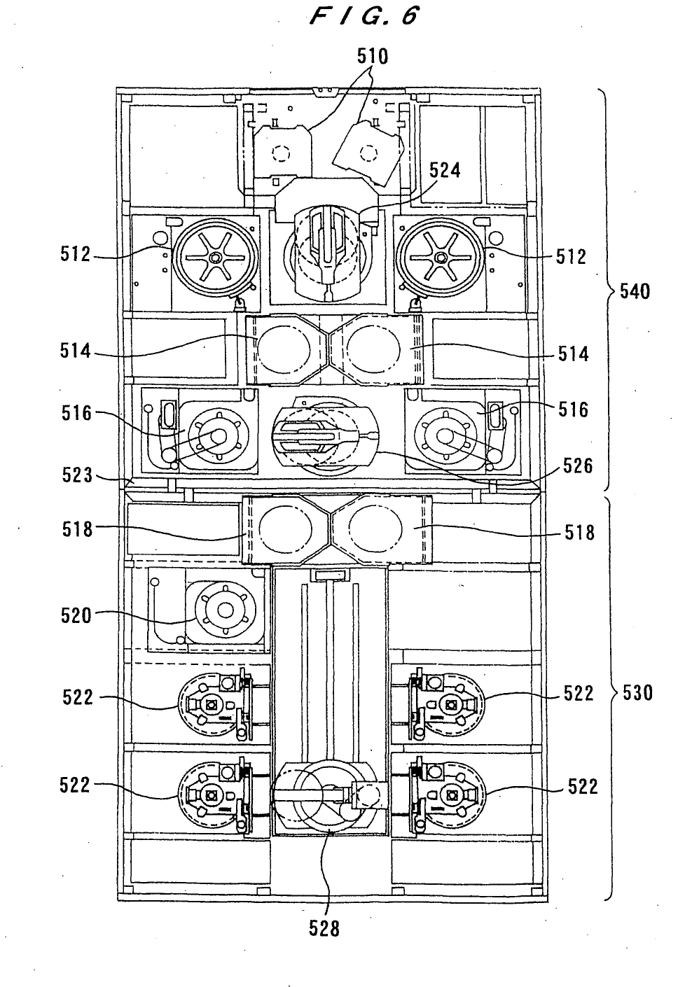

FIG. 6 is a plan view of an example of a substrate plating apparatus. The substrate plating apparatus comprises loading/unloading sections 510, each pair of cleaning/drying sections 512, first substrate stages 514, bevel-etching/chemical cleaning sections 516 and second substrate stages 518, a washing section 520 provided with a mechanism for reversing the substrate through 180°, and four plating devices 522. The plating substrate apparatus is also provided with a first transferring device 524 for transferring a substrate between the loading/unloading sections 510, the cleaning/drying sections 512 and the first substrate stages 514, a second transferring device 526 for transferring a substrate between the first substrate stages 514, the bevel-etching/chemical cleaning sections 516 and the second substrate stages 518, and a third transferring device 528 for transferring the substrate between the second substrate stages 518, the washing section 520 and the plating devices 522.

The substrate plating apparatus has a partition wall 523 for dividing the plating apparatus into a plating space 530 and a clean space 540. Air can individually be supplied into and exhausted from each of the plating space 530 and the clean space 540. The partition wall 523 has a shutter (not shown) capable of opening and closing. The pressure of the clean space 540 is lower than the atmospheric pressure and higher than the pressure of the plating space 530. This can prevent the air in the clean space 540 from flowing out of the plating apparatus and can prevent the air in the plating space 530 from flowing into the clean space 540.

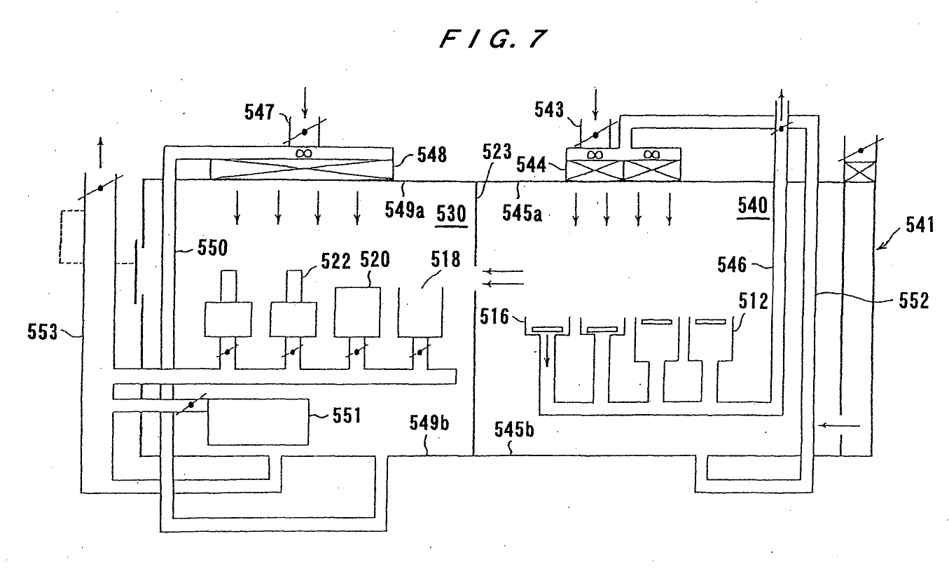

FIG. 7 is a schematic view showing an air current in the plating substrate apparatus. In the clean space 540, a fresh external air is introduced through a pipe 543 and pushed into the clean space 540 through a high-performance filter 544 by a fan. Hence, a down-flow clean air is supplied from a ceiling 545a to positions around the cleaning/drying sections 512 and the bevel-etching/chemical cleaning sections 516. A large part of the supplied clean air is returned from a floor 545b through a circulation pipe 552 to the ceiling 545a, and pushed again into the clean space 540 through the high-performance filter 544 by the fan, to thus circulate in the clean space 540. A part of the air is discharged from the cleaning/drying sections 512 and the bevel-etching/chemical cleaning sections 516 through a pipe 546 to the exterior, so that the pressure of the clean space 540 is set to be lower than the atmospheric pressure.

The plating space 530 having the washing sections 520 and the plating devices 522 therein is not a clean space (but a contamination zone). However, it is not acceptable to attach particles to the surface of the substrate. Therefore, in the plating space 530, a fresh external air is introduced through a pipe 547, and a down-flow-clean air is pushed into the plating space 530 through a high-performance filter 548 by a fan, for thereby preventing particles from being attached to the surface of the substrate. However, if the whole flow rate of the down-flow clean air is supplied by only an external air supply and exhaust, then enormous air supply and exhaust are required. Therefore, the air is discharged through a pipe 553 to the exterior, and a large part of the down-flow is supplied by a circulating air through a circulation pipe 550 extended from a floor 549b, in such a state that the pressure of the plating space 530 is maintained to be lower than the pressure of the clean space 540.

Thus, the air returned to a ceiling 549a through the circulation pipe 550 is pushed again into the plating space 530 through the high-performance filter 548 by the fan. Hence, a clean air is supplied into the plating space 530 to thus circulate in the plating space 530. In this case, air containing chemical mist or gas emitted from the washing sections 520, the plating sections 522, the third transferring device 528, and a plating solution regulating bath 551 is discharged through the pipe 553 to the exterior. Thus, the pressure of the plating space 530 is controlled so as to be lower than the pressure of the clean space 540.

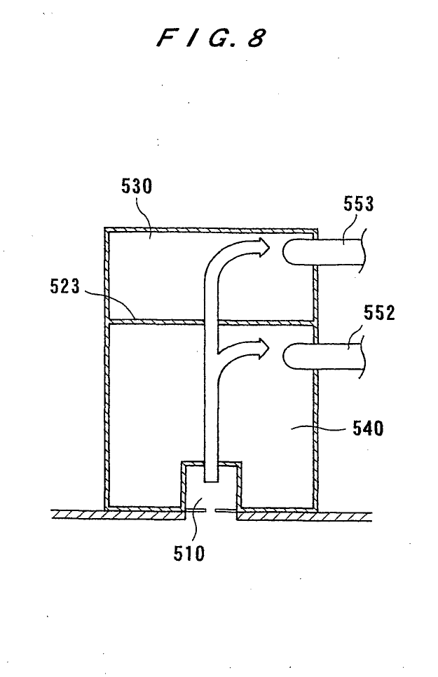

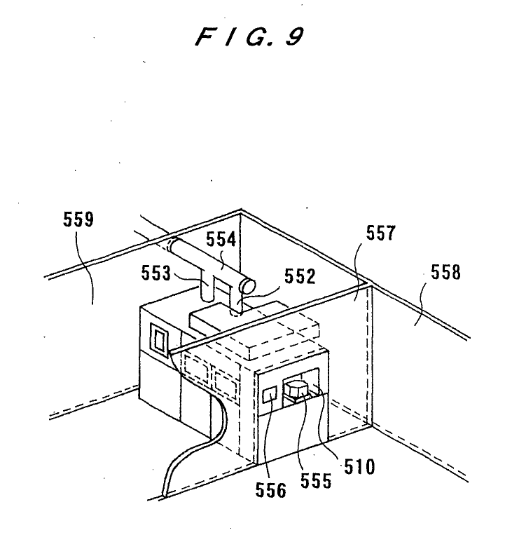

The pressure in the loading/unloading sections 510 is higher than the pressure in the clean space 540 which is higher than the pressure in the plating space 530. When the shutters (not shown) are opened, therefore, air flows successively through the loading/unloading sections 510, the clean space 540, and the plating space 530, as shown in FIG. 8. Air discharged from the clean space 540 and the plating space 530 flows through the ducts 552, 553 into a common duct 554 (see FIG. 9) which extends out of the clean room.

FIG. 9 shows in perspective the substrate plating apparatus shown in FIG. 6, which is placed in the clean room. The loading/unloading sections 510 includes a side wall which has a cassette transfer port 555 defined therein and a control panel 556, and which is exposed to a working zone 558 that is compartmented in the clean room by a partition wall 557. The partition wall 557 also compartments a utility zone 559 in the clean room in which the substrate plating apparatus is installed. Other sidewalls of the substrate plating apparatus are exposed to the utility zone 559 whose air cleanness is lower than the air cleanness in the working zone 558.

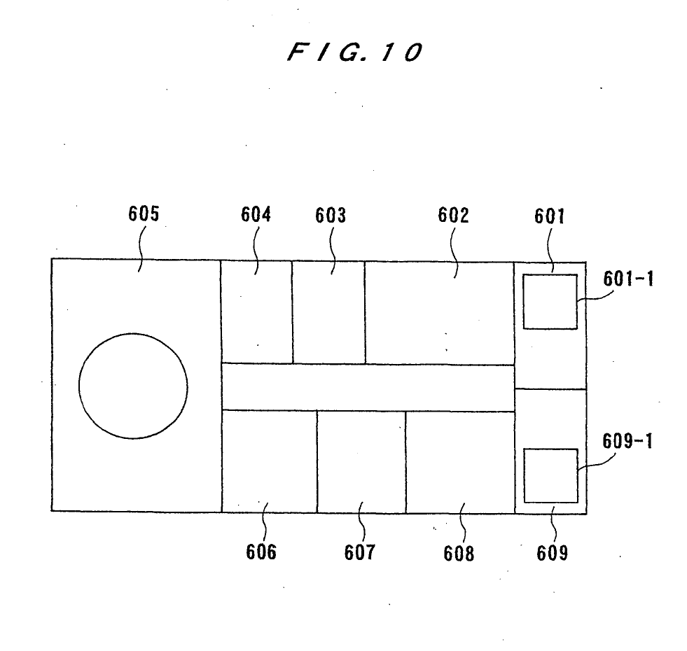

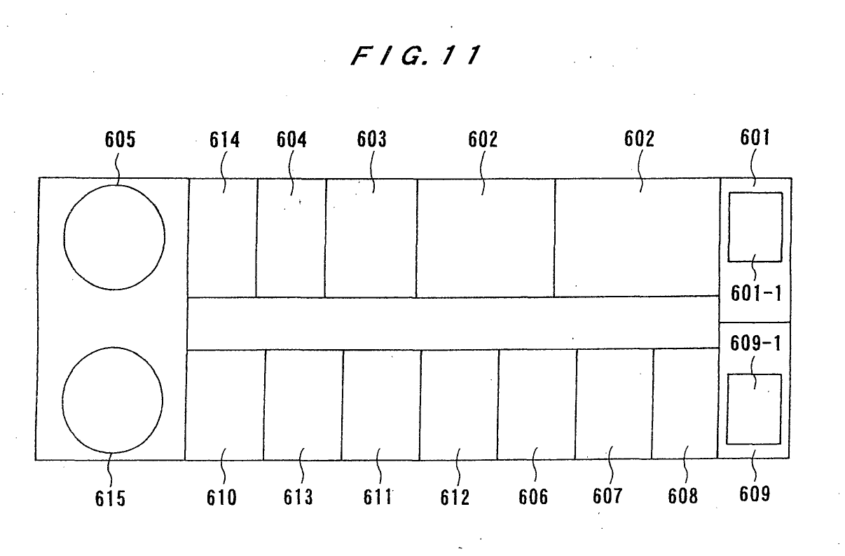

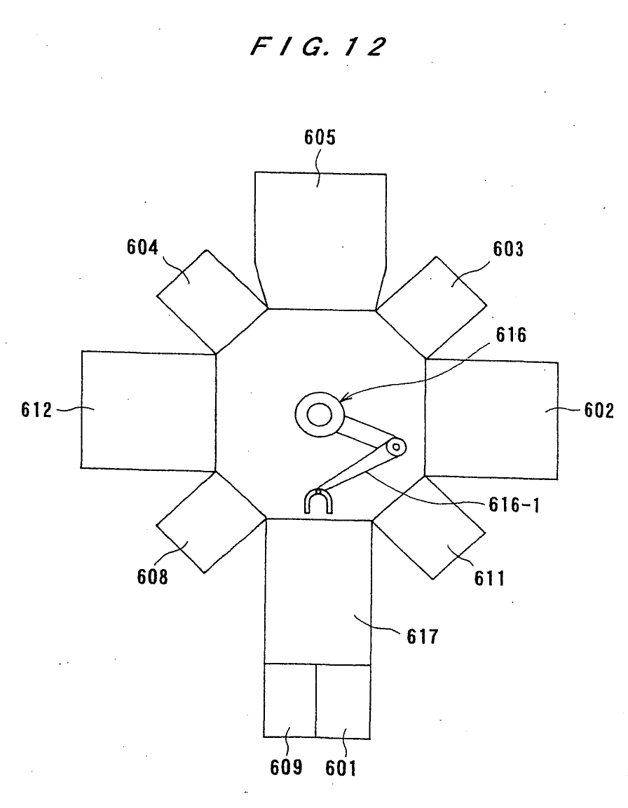

FIG. 10 is a plan view of an example of an apparatus for manufacturing a semiconductor device. The apparatus for manufacturing, a semiconductor device shown in FIG. 10 comprises a loading unit 601 for loading a semiconductor substrate, a copper plating chamber 602 for plating a semiconductor substrate with copper, a pair of water cleaning chambers 603, 604 for cleaning a semiconductor substrate with water, a chemical mechanical polishing unit 605 for chemically and mechanically polishing a semiconductor substrate, a pair of water cleaning chambers 606, 607 for cleaning a semiconductor substrate with water, a drying chamber 608 for drying a semiconductor substrate, and an unloading unit 609 for unloading a semiconductor substrate with interconnects thereon. The apparatus for manufacturing a semiconductor device also has a substrate transfer mechanism (not shown) for transferring semiconductor substrates to the chambers 602, 603, 604, the chemical mechanical polishing unit 605, the chambers 606, 607, 608, and the unloading unit 609. The loading unit 601, the chambers 602, 603, 604, the chemical mechanical polishing unit 605, the chambers 606, 607, 608, and the unloading unit 609 are combined into a single unitary arrangement as an apparatus.

The apparatus for manufacturing a semiconductor device operates as follows: The substrate transfer mechanism transfers a semiconductor substrate W on which interconnects have not yet been formed from a substrate cassette 601-1 placed in the loading unit 601 to the copper plating chamber 602. In the copper plating chamber 602, a plated copper film is formed on a surface of the semiconductor substrate W having an interconnection region composed of interconnection trenches and an interconnection holes (contact holes).

After the plated copper film is formed on the semiconductor substrate W in the copper plating chamber 602, the semiconductor substrate W is transferred to one of the water cleaning chambers 603, 604 by the substrate transfer mechanism and cleaned by water in one of the water cleaning chambers 603, 604, The cleaned semiconductor substrate W is transferred to the chemical mechanical polishing unit 605 by the substrate transfer mechanism. The chemical mechanical polishing unit 605 removes the unwanted plated copper film from the surface of the semiconductor substrate W, leaving a portion of the plated copper film in the interconnection trenches and the interconnection holes. A barrier layer made of TiN or the like is formed on the surface of the semiconductor substrate W including the inner surfaces of the interconnection trenches and the interconnection holes, before the plated copper film is deposited.

Then, the semiconductor substrate W with the remaining plated copper film is transferred to one of the water cleaning chambers 606, 607 by the substrate transfer mechanism and cleaned by water in one of the water cleaning chambers 606, 607. The cleaned semiconductor substrate W is then dried in the drying chamber 608, after which the dried semiconductor substrate W with the remaining plated copper film serving as interconnects is placed into a substrate cassette 609-1 in the unloading unit 609.

FIG. 11 shows a plan view of another example of an apparatus for manufacturing a semiconductor device. The apparatus for manufacturing a semiconductor device shown in FIG. 11 differs from the apparatus for manufacturing a semiconductor device shown in FIG. 10 in that it additionally includes a copper plating chamber 602, a water cleaning chamber 610, protective film forming chambers (electroless plating devices) 611, 612 for forming a protective film on the interconnects on a semiconductor substrate, water cleaning chambers 613, 614, and a chemical mechanical polishing unit 615. The loading unit 601, the chambers 602, 602, 603, 604, 614, the chemical mechanical polishing unit 605, 615, the chambers 606, 607, 608, 610, 611, 612, 613, and the unloading unit 609 are combined into a single unitary arrangement as an apparatus.

The apparatus for manufacturing a semiconductor device shown in FIG. 11 operates as follows: A semiconductor substrate W is supplied from the substrate cassette 601-1 placed in the loading unit 601 successively to one of the copper plating chambers 602, 602. In one of the copper plating chamber 602, 602, a plated copper film is formed on a surface of a semiconductor substrate W having an interconnection region composed of interconnection trenches and interconnection holes (contact holes). The two copper plating chambers 602, 602 are employed to allow the semiconductor substrate W to be plated with a copper film for a long period of time. Specifically, the semiconductor substrate W may be plated with a primary copper film according to electroless plating in one of the copper plating chamber 602, and then plated with a secondary copper film according to electroplating in the other copper plating chamber 602. The apparatus for manufacturing a semiconductor device may have more than two copper plating chambers.

The semiconductor substrate W with the plated copper film formed thereon is cleaned by water in one of the water cleaning chambers 603, 604. Then, the chemical mechanical polishing unit 605 removes the unwanted portion of the plated copper film from the surface of the semiconductor substrate W, leaving a portion of the plated copper film in the interconnection trenches and the interconnection holes.

Thereafter, the semiconductor substrate W with the remaining plated copper film is transferred to the water cleaning chamber 610, in which the semiconductor substrate W is cleaned with water. Then, the semiconductor substrate W is transferred to the protective film forming chamber 611, and formed a thermal diffusion-preventing layer selectively on the surface of the interconnects (plated copper film) in the interconnection region on the semiconductor substrate W. After semiconductor substrate is cleaned in one of the water cleaning chambers 613, 614, the semiconductor substrate W is transferred to another protective film forming chamber 612. In the protective film forming chamber 612, an oxidation-preventing layer is formed selectively on the surface of the thermal diffusion-preventing layer.

After semiconductor substrate with the protective film composed of the thermal diffusion-preventing layer and the oxidation-preventing layer is by water in one of the water cleaning chambers 606, 607, dried in the drying chamber 608, and then transferred to the substrate cassette 609-1 in the unloading unit 609.

FIG. 12 is a plan view of still another example of an apparatus for manufacturing a semiconductor device. As shown in FIG. 12, the apparatus for manufacturing a semiconductor device includes a robot 616 at its center which has a robot arm 616-1, and also has a copper plating chamber 602, a pair of water cleaning chambers 603, 604, a chemical mechanical polishing unit 605, protective film forming chambers (electroless plating devices) 611, 612, a drying chamber 608, and a loading/unloading station 617 which are disposed around the robot 616 and positioned within the reach of the robot arm 616-1. A loading unit 601 for loading semiconductor substrates and an unloading unit 609 for unloading semiconductor substrates is disposed adjacent to the loading/unloading station 617. The robot 616, the chambers 602, 603, 604, the chemical mechanical polishing unit 605, the chambers 608, 611, 612, the loading/unloading station 617, the loading unit 601, and the unloading unit 609 are combined into a single unitary arrangement as an apparatus.

The apparatus for manufacturing a semiconductor device shown in FIG. 12 operates as follows:

A semiconductor substrate to be plated is transferred from the loading unit 601 to the loading/unloading station 617, from which the semiconductor substrate is received by the robot arm 616-1 and transferred thereby to the copper plating chamber 602. In the copper plating chamber 602, a plated copper film is formed on a surface of the semiconductor substrate which has an interconnection region composed of interconnection trenches and interconnection holes. The semiconductor substrate W with the plated copper film formed thereon is transferred by the robot arm 616-1 to the chemical mechanical polishing unit 605. In the chemical mechanical polishing unit 605, the plated copper film is removed from the surface of the semiconductor substrate W, leaving a portion of the plated copper film in the interconnection trenches and the interconnection holes.

The semiconductor substrate is then transferred by the robot arm 616-1 to the water-cleaning chamber 604, in which the semiconductor substrate is cleaned by water. Thereafter, the semiconductor substrate is transferred by the robot arm 616-1 to the protective film forming chamber 611, in which a thermal diffusion-preventing layer is formed selectively on the surface of the interconnects (plated copper film) in the interconnection region on the semiconductor substrate W. After semiconductor substrate is cleaned in one of the water cleaning chambers 604, the semiconductor substrate W is transferred by the robot arm 616-1 to the protective film forming chamber 612. In the protective film forming chamber 612, an oxidation-preventing layer is formed selectively on the surface of the thermal diffusion-preventing layer. The semiconductor substrate with the protective film composed of the thermal diffusion-preventing layer and the oxidation-preventing layer is transferred by the robot arm 616-1 to the water cleaning chamber 604, in which the semiconductor substrate is cleaned by water. The cleaned semiconductor substrate is transferred by the robot arm 616-1 to the drying chamber 608, in which the semiconductor substrate is dried. The dried semiconductor substrate is transferred by the robot arm 616-1 to the loading/unloading station 617, from which the plated semiconductor substrate is transferred to the unloading unit 609.

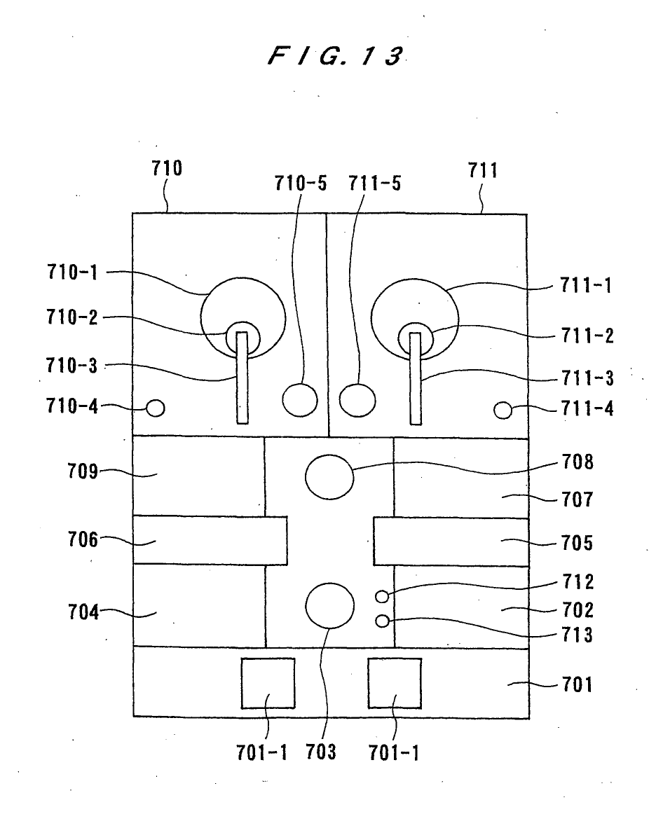

FIG. 13 is a view showing the plan constitution of another example of an apparatus for manufacturing a semiconductor device. The apparatus for manufacturing a semiconductor device is of a constitution in which there are provided a loading/unloading section 701, a plated Cu film forming unit 702, a first robot 703, a third cleaning machine 704, a reversing machine 705, a reversing machine 706, a second cleaning machine 707, a second robot 708, a first cleaning machine 709, a first polishing apparatus 710, and a second polishing apparatus 711. A before-plating and after-plating film thickness measuring instrument 712 for measuring the film thicknesses before and after plating, and a dry state film thickness measuring instrument 713 for measuring the film thickness of a semiconductor substrate W in a dry state after polishing are placed near the first robot 703.

The first polishing apparatus (polishing unit) 710 has a polishing table 710-1, a top ring 710-2, a top ring head 710-3, a film thickness measuring instrument 710-4, and a pusher 710-5. The second polishing apparatus (polishing unit) 711 has a polishing table 711-1, a top ring 711-2, a top ring head 711-3, a film thickness measuring instrument 711-4, and a pusher 711-5.

A cassette 701-1 accommodating the semiconductor substrates W, in which via holes and trenches for interconnect are formed, and a seed layer is formed thereon is placed on a loading port of the loading/unloading section 701. The first robot 703 takes out the semiconductor substrate W from the cassette 701-1, and carries the semiconductor substrate W into the plated Cu film forming unit 702 where a plated Cu film is formed. At this time, the film thickness of the seed layer is measured with the before-plating and after-plating film thickness measuring instrument 712. The plated Cu film is formed by carrying out hydrophilic treatment of the face of the semiconductor substrate W, and then Cu plating. After formation of the plated Cu film, rinsing or cleaning of the semiconductor substrate W is carried out in the plated Cu film forming unit 702.

When the semiconductor substrate W is taken out from the plated Cu film forming unit 702 by the first robot 703, the film thickness of the plated Cu film is measured with the before-plating and after-plating film thickness measuring instrument 712. The results of its measurement are recorded into a recording device (not shown) as record data on the semiconductor substrate, and are used for judgment of an abnormality of the plated Cu film forming unit 702. After measurement of the film thickness, the first robot 703 transfers the semiconductor substrate W to the reversing machine 705, and the reversing machine 705 reverses the semiconductor substrate W (the surface on which the plated Cu film has been formed faces downward). The first polishing apparatus 710 and the second polishing apparatus 711 perform polishing in a serial mode and a parallel mode. Next, polishing in the serial mode will be described.

In the serial mode polishing, a primary polishing is performed by the polishing apparatus 710, and a secondary polishing is performed by the polishing apparatus 711. The second robot 708 picks up the semiconductor substrate W on the reversing machine 705, and places the semiconductor substrate W on the pusher 710-5 of the polishing apparatus 710. The top ring 710-2 attracts the semiconductor substrate W on the pusher 710-5 by suction, and brings the surface of the plated Cu film of the semiconductor substrate W into contact with a polishing surface of the polishing table 710-1 under pressure to perform a primary polishing. With the primary polishing, the plated Cu film is basically polished. The polishing surface of the polishing table 710-1 is composed of foamed polyurethane such as IC1000, or a material having abrasive grains fixed thereto or impregnated therein. Upon relative movements of the polishing surface and the semiconductor substrate W, the plated Cu film is polished.

After completion of polishing of the plated Cu film, the semiconductor substrate W is returned onto the pusher 710-5 by the top ring 710-2. The second robot 708 picks up the semiconductor substrate W, and introduces it into the first cleaning machine 709. At this time, a chemical liquid may be ejected toward the face and backside of the semiconductor substrate W on the pusher 710-5 to remove particles therefrom or cause particles to be difficult to adhere thereto.

After completion of cleaning in the first cleaning machine 709, the second robot 708 picks up the semiconductor substrate W, and places the semiconductor substrate W on the pusher 711-5 of the second polishing apparatus 711. The top ring 711-2 attracts the semiconductor substrate W on the pusher 711-5 by suction, and brings the surface of the semiconductor substrate W, which has the barrier layer formed thereon, into contact with a polishing surface of the polishing table 711-1 under pressure to perform the secondary polishing. The constitution of the polishing table is the same as the top ring 711-2. With this secondary polishing, the barrier layer is polished. However, there may be a case in which a Cu film and an oxide film left after the primary polishing are also polished.

A polishing surface of the polishing table 711-1 is composed of foamed polyurethane such as IC1000, or a material having abrasive grains fixed thereto or impregnated therein. Upon relative movements of the polishing surface and the semiconductor substrate W, polishing is carried out. At this time, silica, alumina, ceria, or the like is used as abrasive grains or slurry. A chemical liquid is adjusted depending on the type of the film to be polished.

Detection of an end point of the secondary polishing is performed by measuring the film thickness of the barrier layer mainly with the use of the optical film thickness measuring instrument, and detecting the film thickness which has become zero, or the surface of an insulating film comprising SiO₂ shows up. Furthermore, a film thickness measuring instrument with an image processing function is used as the film thickness measuring instrument 711-4 provided near the polishing table 711-1. By use of this measuring instrument, measurement of the oxide film is made, the results are stored as processing records of the semiconductor substrate W, and used for judging whether the semiconductor substrate W in which secondary polishing has been finished can be transferred to a subsequent step or not. If the end point of the secondary polishing is not reached, re-polishing is performed. If over-polishing has been performed beyond a prescribed value due to any abnormality, then the semiconductor substrate processing apparatus is stopped to avoid next polishing so that defective products will not increase.

After completion of the secondary polishing, the semiconductor substrate W is moved to the pusher 711-5 by the top ring 711-2. The second robot 708 picks up the semiconductor substrate W on the pusher 711-5. At this time, a chemical liquid may be ejected toward the face and backside of the semiconductor substrate W on the pusher 711-5 to remove particles therefrom or cause particles to be difficult to adhere thereto.

The second robot 708 carries the semiconductor substrate W into the second cleaning machine 707 where cleaning of the semiconductor substrate W is performed. The constitution of the second cleaning machine 707 is also the same as the constitution of the first cleaning machine 709. The face of the semiconductor substrate W is scrubbed with the PVA sponge rolls using a cleaning liquid comprising pure water to which a surface active agent, a chelating agent, or a pH regulating agent is added. A strong chemical liquid such as DHF is ejected from a nozzle toward the backside of the semiconductor substrate W to perform etching of the diffused Cu thereon. If there is no problem of diffusion, scrubbing cleaning is performed with the PVA sponge rolls using the same chemical liquid as that used for the face.

After completion of the above cleaning, the second robot 708 picks up the semiconductor substrate W and transfers it to the reversing machine 706, and the reversing machine 706 reverses the semiconductor substrate W. The semiconductor substrate W which has been reversed is picked up by the first robot 703, and transferred to the third cleaning machine 704. In the third cleaning machine 704, megasonic water excited by ultrasonic vibrations is ejected toward the face of the semiconductor substrate W to clean the semiconductor substrate W. At this time, the face of the semiconductor substrate W may be cleaned with a known pencil type sponge using a cleaning liquid comprising pure water to which a surface active agent, a chelating agent, or a pH regulating agent is added. Thereafter, the semiconductor substrate W is dried by spin-drying.

As described above, if the film thickness has been measured with the film thickness measuring instrument 711-4 provided near the polishing table 711-1, then the semiconductor substrate W is not subjected to further process and is accommodated into the cassette placed on the unloading port of the loading/unloading section 701.

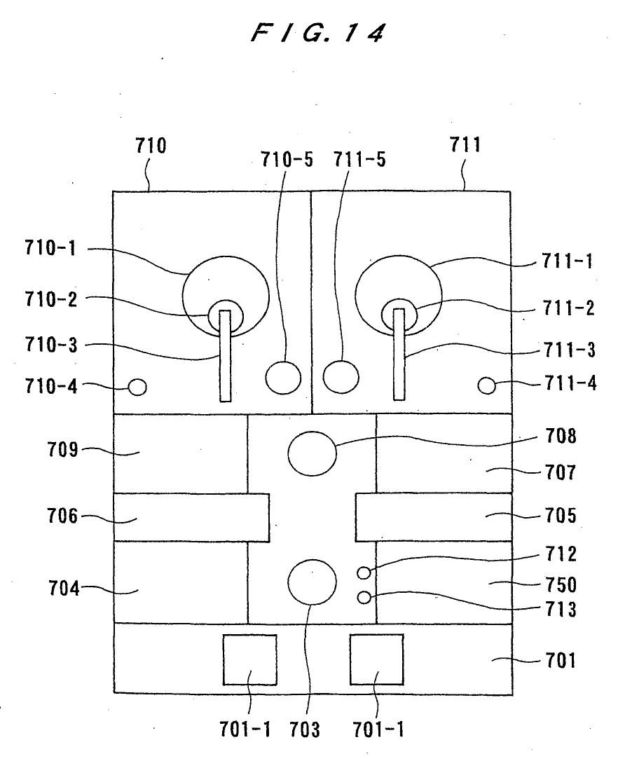

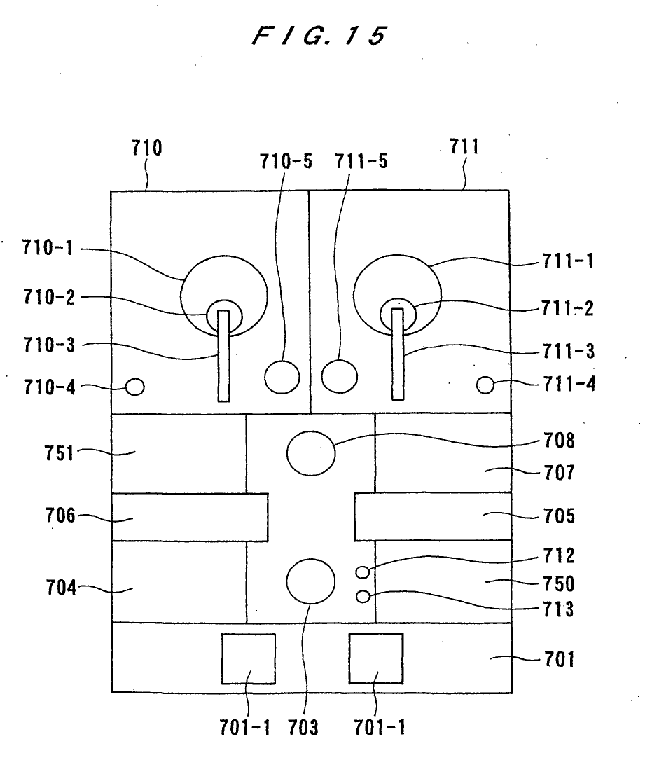

FIG. 14 is a view showing the plan constitution of another example of an apparatus for manufacturing a semiconductor device. The apparatus for manufacturing a semiconductor device differs from the apparatus for manufacturing a semiconductor device shown in FIG. 13 in that a cap plating unit (electroless plating device) 750 for forming a protective film composed of a multi-layer laminated film on the copper interconnect is provided instead of the plated Cu film forming unit 702 in FIG. 13.

A cassette 701-1 accommodating the semiconductor substrates W formed plated Cu film is placed on a load port of a loading/unloading section 701. The semiconductor substrate W taken out from the cassette 701-1 is transferred to the first polishing apparatus 710 or second polishing apparatus 711 in which the surface of the plated Cu film is polished. After completion of polishing of the plated Cu film, the semiconductor substrate W is cleaned in the first cleaning machine 709.

After completion of cleaning in the first cleaning machine 709, the semiconductor substrate W is transferred to the cap plating unit 750 where cap plating for forming a protective film composed of a multi-layer laminated film is applied onto the surface of the interconnects (plated Cu film) with the aim of preventing oxidation of interconnects due to the atmosphere. The semiconductor substrate to which cap plating has been applied is carried by the second robot 708 from the cap plating unit 750 to the second cleaning machine 707 where it is cleaned with pure water or deionized water. The semiconductor substrate after completion of cleaning is returned into the cassette 701-1 placed on the loading/unloading section 701.

FIG. 15 is a view showing the plan constitution of still another example of an apparatus for manufacturing a semiconductor device. The apparatus for manufacturing a semiconductor device differs from the substrate processing apparatus shown in FIG. 14 in that an annealing unit 751 is provided instead of the first cleaning machine 709 in FIG. 14.

The semiconductor substrate W, which is polished in the polishing unit 710 or 711, and cleaned in the second cleaning machine 707 described above, is transferred to the cap plating unit 750 where cap plating is applied onto the surface of the plated Cu film. The semiconductor substrate to which cap plating has been applied is carried by the second robot 708 from the cap plating unit 750 to the second cleaning machine 707 where it is cleaned.

After completion of cleaning in the second cleaning machine 707, the semiconductor substrate W is transferred to the annealing unit 751 in which the substrate is annealed, whereby the plated Cu film is alloyed so as to increase the electromigration resistance of the plated Cu film. The semiconductor substrate W to which annealing treatment has been applied is carried from the annealing unit 751 to the second cleaning machine 707 where it is cleaned with pure water or deionized water. The semiconductor substrate W after completion of cleaning is returned into the cassette 701-1 placed on the loading/unloading section 701.

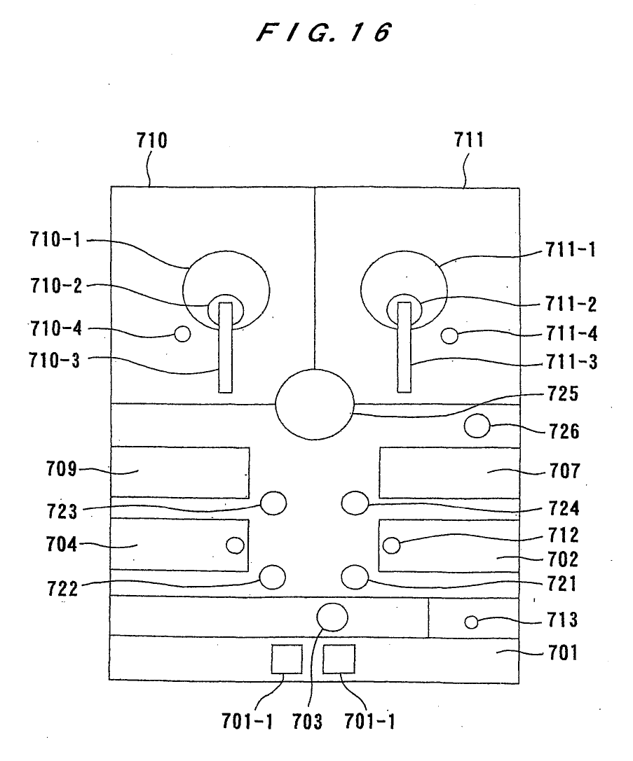

FIG. 16 is a view showing a plan layout constitution of another example of an apparatus for manufacturing a semiconductor device. In FIG. 16, portions denoted by the same reference numerals as those in FIG. 13 show the same or corresponding portions. In the apparatus for manufacturing a semiconductor device, a pusher indexer 725 is disposed close to a first polishing apparatus 710 and a second polishing apparatus 711. Substrate placing tables 721, 722 are disposed close to a third cleaning machine 704 and a plated Cu film forming unit 702, respectively. A robot 723 is disposed close to a first cleaning machine 709 and the third cleaning machine 704. Further, a robot 724 is disposed close to a second cleaning machine 707 and the plated Cu film forming unit 702, and a dry state film thickness measuring instrument 713 is disposed close to a loading/unloading section 701 and a first robot 703.

In the apparatus for manufacturing a semiconductor device of the above constitution, the first robot 703 takes out a semiconductor substrate W from a cassette 701-1 placed on the load port of the loading/unloading section 701. After the film thicknesses of a barrier layer and a seed layer are measured with the dry state film thickness measuring instrument 713, the first robot 703 places the semiconductor substrate W on the substrate placing table 721. In the case where the dry state film thickness measuring instrument 713 is provided on the hand of the first robot 703, the film thicknesses are measured thereon, and the substrate is placed on the substrate placing table 721. The second robot 723 transfers the semiconductor substrate W on the substrate placing table 721 to the plated Cu film forming unit 702 in which a plated Cu film is formed. After formation of the plated Cu film, the film thickness of the plated Cu film is measured with a before-plating and after-plating film thickness measuring instrument 712. Then, the second robot 723 transfers the semiconductor substrate W to the pusher indexer 725 and loads it thereon.

[Serial Mode]

In the serial mode, a top ring 710-2 holds the semiconductor substrate W on the pusher indexer 725 by suction, transfers it to a polishing table 710-1, and presses the semiconductor substrate W against a polishing surface on the polishing table 710-1 to perform polishing. Detection of the end point of polishing is performed by the same method as described above. The semiconductor substrate W after completion of polishing is transferred to the pusher indexer 725 by the top ring 710-2, and loaded thereon. The second robot 723 takes out the semiconductor substrate W, and carries it into the first cleaning machine 709 -for cleaning. Then, the semiconductor substrate W is transferred to the pusher indexer 725, and loaded thereon.

A top ring 711-2 holds the semiconductor substrate W on the pusher indexer 725 by suction, transfers it to a polishing table 711-1, and presses the semiconductor substrate W against a polishing surface on the polishing table 711-1 to perform polishing. Detection of the end point of polishing is performed by the same method as described above. The semiconductor substrate W after completion of polishing is transferred to the pusher indexer 725 by the top ring 711-2, and loaded thereon. The third robot 724 picks up the semiconductor substrate W, and its film thickness is measured with a film thickness measuring instrument 726. Then, the semiconductor substrate W is carried into the second cleaning machine 707 for cleaning. Thereafter, the semiconductor substrate W is carried into the third cleaning machine 704, where it is cleaned and then dried by spin-drying. Then, the semiconductor substrate W is picked up by the third robot 724, and placed on the substrate placing table 722.

[Parallel mode]

In the parallel mode, the top ring 710-2 or 711-2 holds the semiconductor substrate W on the pusher indexer 725 by suction, transfers it to the polishing table 710-1 or 711-1, and presses the semiconductor substrate W against the polishing surface on the polishing table 710-1 or 711-1 to perform polishing. After measurement of the film thickness, the third robot 724 picks up the semiconductor substrate W, and places it on the substrate placing table 722.

The first robot 703 transfers the semiconductor substrate W on the substrate placing table 722 to the dry state film thickness measuring instrument 713. After the film thickness is measured, the semiconductor substrate W is returned to the cassette 701-1 of the loading/unloading section 701.

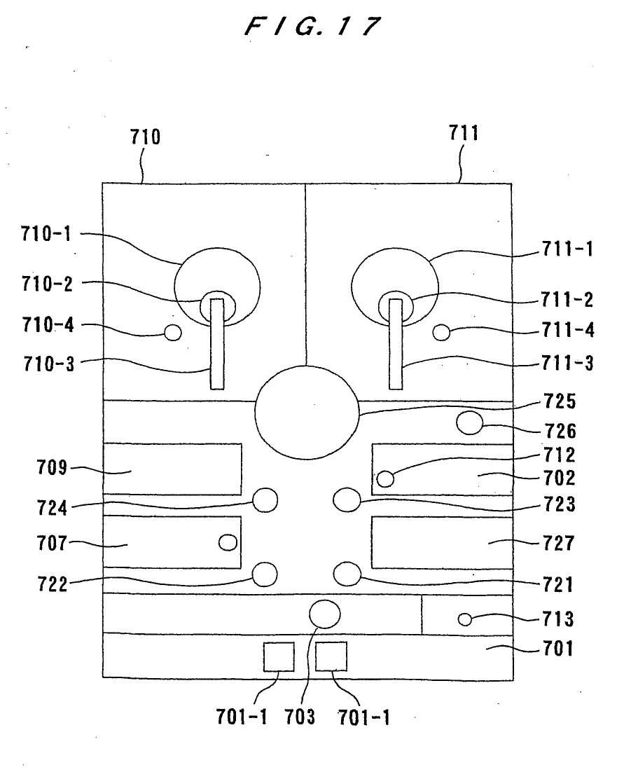

FIG. 17 is a view showing another plan layout constitution of an apparatus for manufacturing a semiconductor device. The apparatus for manufacturing a semiconductor device is such an apparatus which forms a seed layer and a plated Cu film on a semiconductor substrate W having no seed layer formed thereon, and polishes these films to form interconnects.

In the apparatus for manufacturing a semiconductor device, a pusher indexer 725 is disposed close to a first polishing apparatus 710 and a second polishing apparatus 711, substrate placing tables 721, 722 are disposed close to a second cleaning machine 707 and a seed layer forming unit 727, respectively, and a robot 723 is disposed close to the seed layer forming unit 727 and a plated Cu film forming unit 702. Further, a robot 724 is disposed close to a first cleaning machine 709 and the second cleaning machine 707, and a dry state film thickness measuring instrument 713 is disposed close to a loading/unloading section 701 and a first robot 703.

The first robot 703 takes out a semiconductor substrate W having a barrier layer thereon from a cassette 701-1 placed on the load port of the loading/unloading section 701, and places it on the substrate placing table 721. Then, the second robot 723 transfers the semiconductor substrate W to the seed layer forming unit 727 where a seed layer is formed. The seed layer is formed by electroless plating. The second robot 723 enables the semiconductor substrate having the seed layer formed thereon to be measured in thickness of the seed layer by the before-plating and after-plating film thickness measuring instrument 712. After measurement of the film thickness, the semiconductor substrate is carried into the plated Cu film forming unit 702 where a plated Cu film is formed.

After formation of the plated Cu film, its film thickness is measured, and the semiconductor substrate is transferred to a pusher indexer 725. A top ring 710-2 or 711-2 holds the semiconductor substrate W on the pusher indexer 725 by suction, and transfers it to a polishing table 710-1 or 711-1 to perform polishing. After polishing, the top ring 710-2 or 711-2 transfers the semiconductor substrate W to a film thickness measuring instrument 710-4 or 711-4 to measure the film thickness. Then, the top ring 710-2 or 711-2 transfers the semiconductor substrate W to the pusher indexer 725, and places it thereon.

Then, the third robot 724 picks up the semiconductor substrate W from the pusher indexer 725, and carries it into the first cleaning machine 709. The third robot 724 picks up the cleaned semiconductor substrate W from the first cleaning machine 709, carries it into the second cleaning machine 707, and places the cleaned and dried semiconductor substrate on the substrate placing table 722. Then, the first robot 703 picks up the semiconductor substrate W, and transfers it to the dry state film thickness measuring instrument 713 in which the film thickness is measured, and the first robot 703, carries it into the cassette 701-1 placed on the unload port of the loading/unloading section 701.

In the apparatus for manufacturing a semiconductor device shown in FIG. 17, interconnects are formed by forming a barrier layer, a seed layer and a plated Cu film on a semiconductor substrate W having via holes or trenches of a circuit pattern formed therein, and polishing them.

The cassette 701-1 accommodating the semiconductor substrates W before formation of the barrier layer is placed on the load port of the loading/unloading section 701. The first robot 703 takes out the semiconductor substrate W from the cassette 701-1 placed on the load port of the loading/unloading section 701, and places it on the substrate placing table 721. Then, the second robot 723 transfers the semiconductor substrate W to the seed layer forming unit 727 where a barrier layer and a seed layer are formed. The barrier layer and the seed layer are formed by electroless plating. The second robot 723 brings the semiconductor substrate W having the barrier layer and the seed layer formed thereon to the before-plating and after-plating film thickness measuring instrument 712 which measures the film thicknesses of the barrier layer and the seed layer. After measurement of the film thicknesses, the semiconductor substrate W is carried into the plated Cu film forming unit 702 where a plated Cu film is formed.

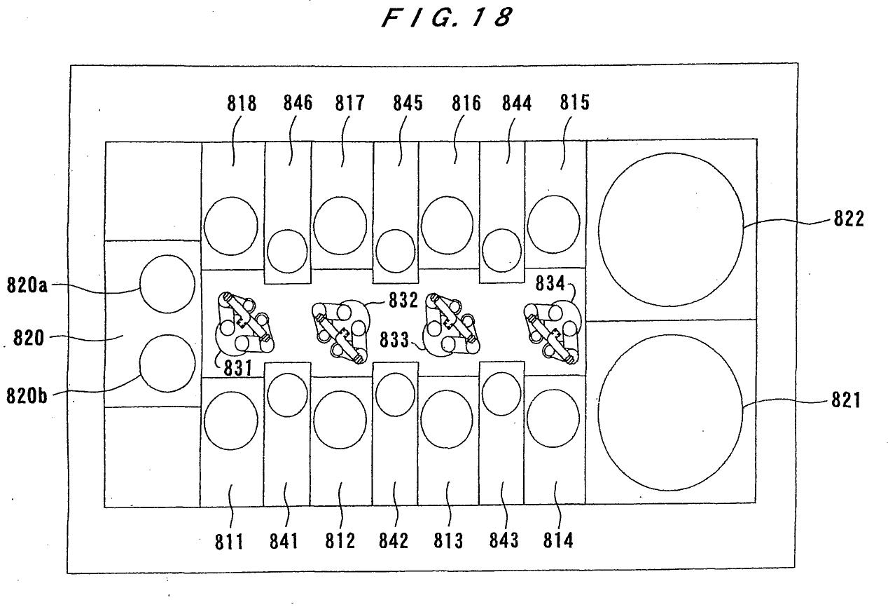

FIG. 18 is a view showing plan layout constitution of another example of an apparatus for manufacturing a semiconductor device. In the apparatus for manufacturing a semiconductor device, there are provided a barrier layer forming unit 811, a seed layer forming unit 812, a plated film forming unit 813, an annealing unit 814, a first cleaning unit 815, a bevel and backside cleaning unit 816, a cap plating unit 817, a second cleaning unit 818, a first aligner and film thickness measuring instrument 841, a second aligner and film thickness measuring instrument 842, a first substrate reversing machine 843, a second substrate reversing machine 844, a substrate temporary placing table 845, a third film thickness measuring instrument 846, a loading/unloading section 820, a first polishing apparatus 821, a second polishing apparatus 822, a first robot 831, a second robot 832, a third robot 833, and a fourth robot 834. The film thickness measuring instruments 841, 842 and 846 are units, have the same size as the frontage dimension of other units (plating, cleaning, annealing units, and the like), and are thus interchangeable.

In this example, an electroless Ru plating apparatus can be used as the barrier layer forming unit 811, an electroless Cu plating apparatus as the seed layer forming unit 812, and an electroplating apparatus as the plated film forming unit 813.

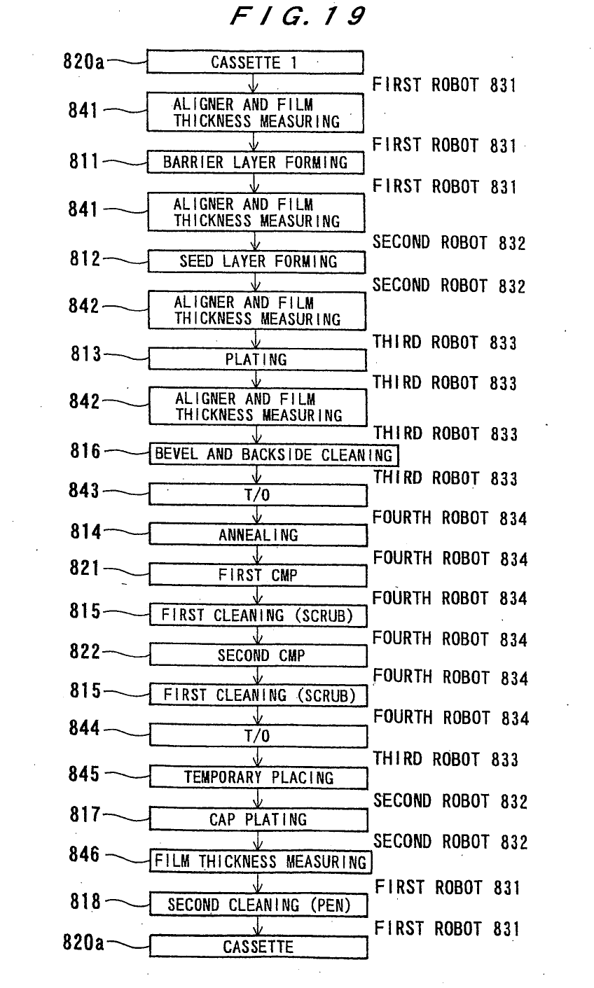

FIG. 19 is a flow chart showing the flow of the respective steps in the present apparatus for manufacturing a semiconductor device. The respective steps in the apparatus will be described according to this flow chart. First, a semiconductor substrate taken out by the first robot 831 from a cassette 820a placed on the load and unload section 820 is placed in the first aligner and film thickness measuring instrument 841, in such a state that its surface, to be plated, faces upward. In order to set a reference point for a position at which film thickness measurement is made, notch alignment for film thickness measurement is performed, and then film thickness data on the semiconductor substrate before formation of a Cu film are obtained.

Then, the semiconductor substrate is transferred to the barrier layer forming unit 811 by the first robot 831. The barrier layer forming unit 811 is such an apparatus for forming a barrier layer on the semiconductor substrate by electroless Ru plating, and the barrier layer forming unit 811 forms an Ru film as a film for preventing Cu from diffusing into an interlevel dielectric film (e.g. SiO₂) of a semiconductor device. The semiconductor substrate discharged after cleaning and drying steps is transferred by the first robot 831 to the first aligner and film thickness measuring instrument 841, where the film thickness of the semiconductor substrate, i.e., the film thickness of the barrier layer is measured.

The semiconductor substrate after film thickness measurement is carried into the seed layer forming unit 812 by the second robot 832, and a seed layer is formed on the barrier layer by electroless Cu plating. The semiconductor substrate discharged after cleaning and drying steps is transferred by the second robot 832 to the second aligner and film thickness measuring instrument, 842 for determination of a notch position, before the semiconductor substrate is transferred to the plated film forming unit 813, which is an impregnation plating unit, and then notch alignment for Cu plating is performed by the film thickness measuring instrument 842. If necessary, the film thickness of the semiconductor substrate before formation of a Cu film may be measured again in the film thickness measuring instrument 842.

The semiconductor substrate which has completed notch alignment is transferred by the third robot 833 to the plated film forming unit 813 where Cu plating is applied to the semiconductor substrate. The semiconductor substrate discharged after cleaning and drying steps is transferred by the third robot 833 to the bevel and backside cleaning unit 816 where an unnecessary Cu film (seed layer) at a peripheral portion of the semiconductor substrate is removed. In the bevel and backside cleaning unit 816, the bevel is etched in a preset time, and Cu adhering to the backside of the semiconductor substrate is cleaned with a chemical liquid such as hydrofluoric acid. At this time, before transferring the semiconductor substrate to the bevel and backside cleaning unit 816, film thickness measurement of the semiconductor substrate may be made by the second aligner and film thickness measuring instrument 842 to obtain the thickness value of the Cu film formed by plating, and based on the obtained results, the bevel etching time may be changed arbitrarily to carry out etching. The region etched by bevel etching is a region which corresponds to a peripheral edge portion of the substrate and has no circuit formed therein, or a region which is not utilized finally as a chip although a circuit is formed. A bevel portion is included in this region.

The semiconductor substrate discharged after cleaning and drying steps in the bevel and backside cleaning unit 816 is transferred by the third robot 833 to the substrate reversing machine 843. After the semiconductor substrate is turned over by the substrate reversing machine 843 to cause the plated surface to be directed downward, the semiconductor substrate is introduced into the annealing unit 814 by the fourth robot 834 for thereby stabilizing an interconnection portion. Before and/or after annealing treatment, the semiconductor substrate is carried into the second aligner and film thickness measuring instrument 842 where the film thickness of a copper film formed on the semiconductor substrate is measured. Then, the semiconductor substrate is carried by the fourth robot 834 into the first polishing apparatus 821 in which the Cu film and the seed layer of the semiconductor substrate are polished.

At this time, desired abrasive grains or the like are used, but fixed abrasive may be used in order to prevent dishing and enhance flatness of the face. After completion of primary polishing, the semiconductor substrate is transferred by the fourth robot 834 to the first cleaning unit 815 where it is cleaned. This cleaning is scrub-cleaning in which rolls having substantially the same length as the diameter of the semiconductor substrate are placed on the face and the backside of the semiconductor substrate, and the semiconductor substrate and the rolls are rotated, while pure water or deionized water is flowed, thereby performing cleaning of the semiconductor substrate.

After completion of the primary cleaning, the semiconductor substrate is transferred by the fourth robot 834 to the second polishing apparatus 822 where the barrier layer on the semiconductor substrate is polished. At this time, desired abrasive grains or the like are used, but fixed abrasive may be used in order to prevent dishing and enhance flatness of the face. After completion of secondary polishing, the semiconductor substrate is transferred by the fourth robot 834 again to the first cleaning unit 815 where scrub-cleaning is performed. After completion of cleaning, the semiconductor substrate is transferred by the fourth robot 834 to the second substrate reversing machine 844 where the semiconductor substrate is reversed to cause the plated surface to be directed upward, and then the semiconductor substrate is placed on the substrate temporary placing table 845 by the third robot.

The semiconductor substrate is transferred by the second robot 832 from the substrate temporary placing table 845 to the cap plating unit 817 where cap plating for forming a protective film composed of a multi-layer laminated film is applied onto the Cu surface with the aim of preventing oxidation of Cu due to the atmosphere. The semiconductor substrate to which cap plating has been applied is carried by the second robot 832 from the cap plating unit 817 to the third film thickness measuring instrument 846 where the thickness of the copper film is measured. Thereafter, the semiconductor substrate is carried by the first robot 831 into the second cleaning unit 818 where it is cleaned with pure water or deionized water. The semiconductor substrate after completion of cleaning is returned into the cassette 820a placed on the loading/unloading section 820.

The aligner and film thickness measuring instrument 841 and the aligner and film thickness measuring instrument 842 perform positioning of the notch portion of the substrate and measurement of the film thickness.

The seed layer forming unit 812 may be omitted. In this case, a plated film may be formed on a barrier layer directly in a plated film forming unit 813.

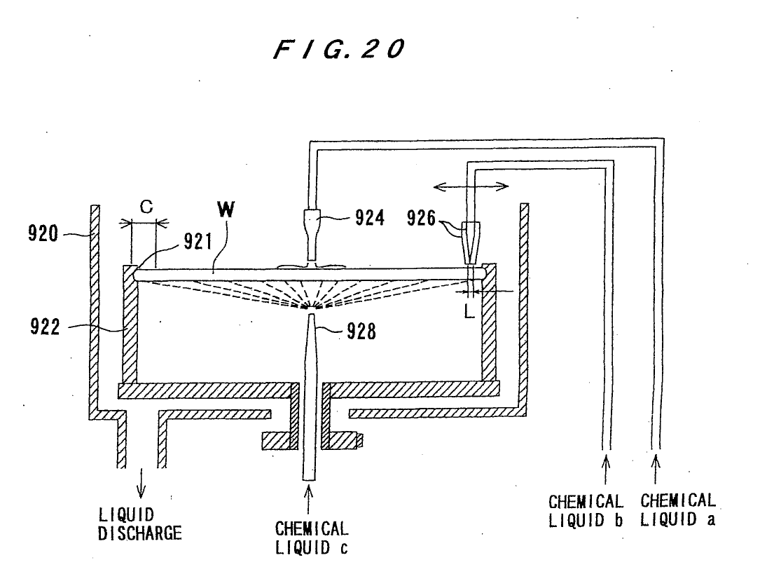

The bevel and backside cleaning unit 816 can perform an edge (bevel) Cu etching and a backside cleaning at the same time, and can suppress growth of a natural oxide film of copper at the circuit formation portion on the surface of the substrate. FIG. 20 shows a schematic view of the bevel and backside cleaning unit 816. As shown in FIG. 20, the bevel and backside cleaning unit 816 has a substrate holding portion 922 positioned inside a bottomed cylindrical waterproof cover 920 and adapted to rotate a substrate W at a high speed, in such a state that the face of the substrate W faces upwardly, while holding the substrate W horizontally by spin chucks 921 at a plurality of locations along a circumferential direction of a peripheral edge portion of the substrate, a center nozzle 924 placed above a nearly central portion of the face of the substrate W held by the substrate holding portion 922, and an edge nozzle 926 placed above the peripheral edge portion of the substrate W. The center nozzle 924 and the edge nozzle, 926 are directed downward. A back nozzle 928 is positioned below a nearly central portion of the backside of the substrate W, and directed upward. The edge nozzle 926 is adapted to be movable in a diametrical direction and a height direction of the substrate W.

The width of movement L of the edge nozzle 926 is set such that the edge nozzle 926 can be arbitrarily positioned in a direction toward the center from the outer peripheral end surface of the substrate, and a set value for L is inputted according to the size, usage, or the like of the substrate W. Normally, an edge cut width C is set in the range of 2 mm to 5 mm. In the case where a rotational speed of the substrate is a certain value or higher at which the amount of liquid migration from the backside to the face is not problematic, the copper film within the edge cut width C can be removed.

Next, the method of cleaning with this cleaning apparatus will be described. First, the semiconductor substrate W is horizontally rotated integrally with the substrate holding portion 922, with the substrate being held horizontally by the spin chucks 921 of the substrate holding portion 922. In this state, an acid solution is supplied from the center nozzle 924 to the central portion of the face of the substrate W. The acid solution may be a non-oxidizing acid, and hydrofluoric acid, hydrochloric acid, sulfuric acid, citric acid, oxalic acid, or the like is used. On the other hand, an oxidizing agent solution is supplied continuously or intermittently from the edge nozzle 926 to the peripheral edge portion of the substrate W. As the oxidizing agent solution, one of an aqueous solution of ozone, an aqueous solution of hydrogen peroxide, an aqueous solution of nitric acid, and an aqueous solution of sodium hypochlorite is used, or a combination of these is used.

In this manner, the copper film, or the like formed on the upper surface and end surface in the region of the peripheral edge portion C of the semiconductor substrate W is rapidly oxidized with the oxidizing agent solution, and is simultaneously etched with the acid solution supplied from the center nozzle 924 and spread on the entire face of the substrate, whereby it is dissolved and removed. By mixing the acid solution and the oxidizing agent solution at the peripheral edge portion of the substrate, a steep etching profile can be obtained, in comparison with a mixture of them which is produced in advance being supplied. At this time, the copper etching rate is determined by their concentrations. If a natural oxide film of copper is formed in the circuit-formed portion on the face of the substrate, this natural oxide is immediately removed by the acid solution spreading on the entire face of the substrate according to rotation of the substrate, and does not grow any more. After the supply of the acid solution from the center nozzle 924 is stopped, the supply of the oxidizing agent solution from the edge nozzle 926 is stopped. As a result, silicon exposed on the surface is oxidized, and deposition of copper can be suppressed.

On the other hand, an oxidizing agent solution and a silicon oxide film etching agent are supplied simultaneously or alternately from the back nozzle 928 to the central portion of the backside of the substrate. Therefore, copper or the like adhering in a metal form to the backside of the semiconductor substrate W can be oxidized with the oxidizing agent solution, together with silicon of the substrate, and can be etched and removed with the silicon oxide film etching agent. This oxidizing agent solution is preferably the same as the oxidizing agent solution supplied to the face, because the types of chemicals are decreased in number. Hydrofluoric acid can be used as the silicon oxide film etching agent, and if hydrofluoric acid is used as the acid solution on the face of the substrate, the types of chemicals can be decreased in number. Thus, if the supply of the oxidizing agent is stopped first, a hydrophobic surface is obtained. If the etching agent solution is stopped first, a water-saturated surface (a hydrophilic surface) is obtained, and thus the backside surface can be adjusted to a condition which will satisfy the requirements of a subsequent process.

In this manner, the acid solution, i.e., etching solution is supplied to the substrate to remove metal ions remaining on the surface of the substrate W. Then, pure water is supplied to replace the etching solution with pure water and remove the etching solution, and then the substrate is dried by spin-drying. In this way, removal of the copper film in the edge cut width C at the peripheral edge portion on the face of the semiconductor substrate, and removal of copper contaminants on the backside are performed simultaneously to thus allow this treatment to be completed, for example, within 80 seconds. The etching cut width of the edge can be set arbitrarily (from 2 to 5 mm), but the time required for etching does not depend on the cut width.

Annealing treatment performed before the CMP process and after plating has a favorable effect on the subsequent CMP treatment and on the electrical characteristics of interconnection. Observation of the surface of broad interconnection (unit of several micrometers) after the CMP treatment without annealing showed many defects such as microvoids, which resulted in an increase in the electrical resistance of the entire interconnection. Execution of annealing ameliorated the increase in the electrical resistance. In the presence of annealing, thin interconnection showed no voids. Thus, the degree of grain growth is presumed to be involved in these phenomena. That is, the following mechanism can be speculated: Grain growth is difficult to occur in thin interconnection. In broad interconnection, on the other hand, grain growth proceeds in accordance with annealing treatment. During the process of grain growth, ultra-fine pores in the plated film, which are too small to be seen by the SEM (scanning electron microscope), gather and move upward, thus forming microvoid-like depressions in the upper part of the interconnection. The annealing conditions in the annealing unit 814 are such that hydrogen (2% or less) is added in a gas atmosphere, the temperature is in the range of 300° C. to 400° C., and the time is in the range of 1 to 5 minutes. Under these conditions, the above effects were obtained.

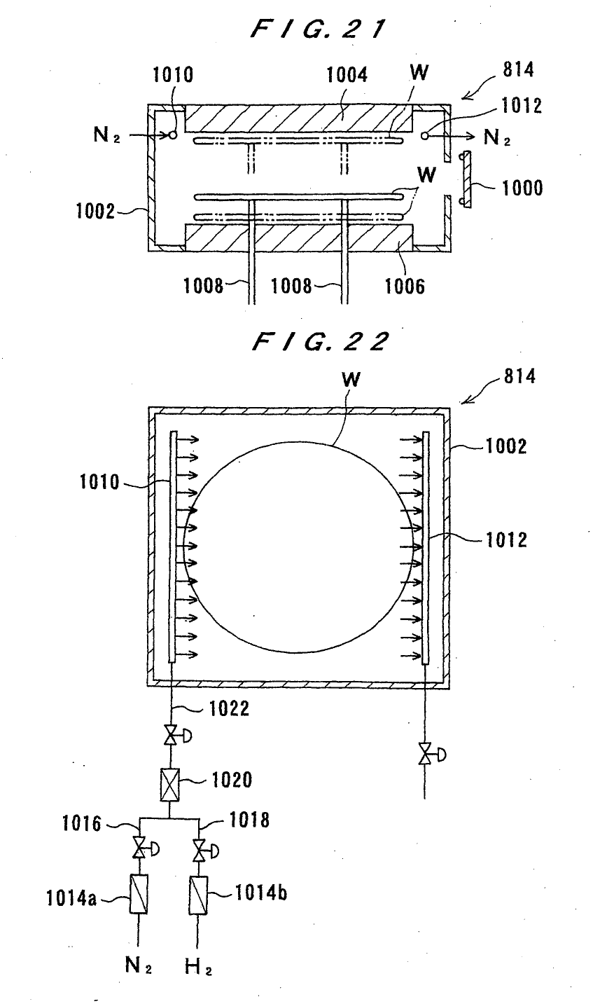

FIGS. 21 and 22 show the annealing unit 814. The annealing unit 814 comprises a chamber 1002 having a gate 1000 for taking in and taking out the semiconductor substrate W, a hot plate 1004 disposed at an upper position in the chamber 1002 for heating the semiconductor substrate W to e.g. 400° C., and a cool plate 1006 disposed at a lower position in the chamber 1002 for cooling the semiconductor substrate W by, for example, flowing a cooling water inside the plate. The annealing unit 814 also has a plurality of vertically movable elevating pins 1008 penetrating the cool plate 1006 and extending upward and downward therethrough for placing and holding the semiconductor substrate W on them. The annealing unit further includes a gas introduction pipe 1010 for introducing an antioxidant gas between the semiconductor substrate W and the hot plate 1004 during annealing, and a gas discharge pipe 1012 for discharging the gas which has been introduced from the gas introduction pipe 1010 and flowed between the semiconductor substrate W and the hot plate 1004. The pipes 1010 and 1012 are disposed on the opposite sides of the hot plate 1004.

The gas introduction pipe 1010 is connected to a mixed gas introduction line 1022 which in turn is connected to a mixer 1020 where a N₂ gas introduced through a N₂ gas introduction line 1016 containing a filter 1014a, and a H₂ gas introduced through a H₂ gas introduction line 1018 containing a filter 1014b, are mixed to form a mixed gas which flows through the line 1022 into the gas introduction pipe 1010.

In operation, the semiconductor substrate W, which has been carried in the chamber 1002 through the gate 1000, is held on the elevating pins 1008 and the elevating pins 1008 are raised up to a position at which the distance between the semiconductor substrate W held on the lifting pins 1008 and the hot plate 1004 becomes e.g. 0.1-1.0 mm. In this state, the semiconductor substrate W is then heated to e.g. 400° C. through the hot plate 1004 and, at the same time, the antioxidant gas is introduced from the gas introduction pipe 1010 and the gas is allowed to flow between the semiconductor substrate W and the hot plate 1004 while the gas is discharged from the gas discharge pipe 1012, thereby annealing the semiconductor substrate W while preventing its oxidation. The annealing treatment may be completed in about several tens of seconds to 60 seconds. The heating temperature of the substrate may be selected in the range of 100-600° C.

After the completion of the annealing, the elevating pins 1008 are lowered down to a position at which the distance between the semiconductor substrate W held on the elevating pins 1008 and the cool plate 1006 becomes e.g. 0-0.5 mm. In this state, by introducing a cooling water into the cool plate 1006, the semiconductor substrate W is cooled by the cool plate to a temperature of 100° C. or lower in e.g. 10-60 seconds. The cooled semiconductor substrate is sent to the next step.

A mixed gas of N₂ gas with several % of H₂ gas is used as the above antioxidant gas. However, N₂ gas may be used singly.

The annealing unit may be placed in the electroplating apparatus.

The following Examples illustrate the present invention but are not intended to limit it.

### EXAMPLE 1

A substrate sample was prepared by depositing TaN of 50 nm thickness onto a silicon substrate, and depositing thereon copper of 600 nm thickness by sputtering, and then carrying out CMP treatment of the copper surface. Using the electroless plating device of FIG. 4, after water-washing the substrate sample, electroless plating of the sample was carried out for one minute by using an electroless plating solution having the composition shown in Table 1 below, thereby-depositing a Co—W—B alloy layer of 50 nm thickness on the surface of the substrate sample.

TABLE 1

| | |
|---|---|
| CoSO₄.7H₂O | 0.10 mol/L |
| L-tartaric acid | 0.50 mol/L |
| (NH₄)₂SO₄ | 0.20 mol/L |
| DMAB | 0.02 mol/L |
| TMAH (27%) | 0.80 mol/L |
| H₂WO₄ | 0.10 mol/L |
| pH | 9 (with ammonia water) |
| Temp. | 80° C. |

Next, after-washing the thus-plated substrate sample, electroless plating of the sample was successively carried out for one minute by using an electroless plating solution having the composition shown in Table 2 below, thereby depositing a Ni—B alloy layer of 40 nm thickness. Thereafter, the plated sample was water-washed and dried.

TABLE 2

| | |
|---|---|
| NiSO₄.6H₂O | 0.02 mol/L |
| Malic acid | 0.02 mol/L |
| Glycine | 0.03 mol/L |
| DMAB | 0.02 mol/L |
| pH | 10 (with ammonia water) |
| Temp. | 60° C. |

### COMPARATIVE EXAMPLES 1 AND 2

Using the electroless plating solution having the composition of Table 1, electroless plating was carried out onto the same substrate sample as used in Example 1, thereby depositing thereon a Co—W—B alloy layer of 100 nm thickness (Comp. Example 1).

Separately, using the electroless plating solution having the composition of Table 2, electroless plating was carried out onto the same substrate sample as used in Example 1, thereby depositing thereon a Ni—B alloy layer of 100 nm thickness (Comp. Example 2).

The plated samples thus obtained in Example 1 and Comp. Examples 1 and 2 were subjected to an oxidation treatment and separately to a heat treatment under the following conditions:

Oxidation treatment: 133 Pa, 800 W, 250° C., 30 min, O₂ atmosphere

Heat treatment: 1×10⁻⁴ Pa, 450° C., 1 hr

After the respective treatments, the sheet resistance of each test sample was measured. The results are shown in Table 3 below.

TABLE 3

| | | | After | After |
|---|---|---|---|---|
| | Type of | After | oxidation | heat |
| Example No. | plating | plating | treatment | treatment |
| Example 1 | Co—W—B + | 83 | 82 | 82 |
| | Ni—B | | | |
| Comp. Example 1 | Co—W—B | 87 | 155 | 89 |
| | (100 nm) | | | |
| Comp. Example 2 | Ni—B | 32 | 32 | 103 |
| | (100 nm) | | | |

(unit: mΩ)

The data in Table 3 shows that: the test sample of Comp. Example 1, which has only the Co alloy (Co—W—B) layer deposited on the copper layer of the substrate, has the sheet resistance value after the oxidation treatment which is about 1.8 times larger than that after the plating, indicating a poor oxidation-preventing effect of the single Co alloy layer; the test sample of Comp. Example 2, which has only the Ni alloy (Ni—B) layer deposited on the copper layer of the substrate, has he sheet resistance value after the heat treatment which is about 3.2 times larger than that after the plating, indicating a poor thermal diffusion-preventing effect of the single Ni alloy layer. In contrast, in the case of the test sample of Example 1 according to the present invention, the sheet resistance value after the oxidation treatment and that after the heat treatment are both substantially the same as the sheet resistance value after the plating, indicating that the lamination of the two alloy layers has a marked effect in preventing both of the oxidation and the thermal diffusion of copper.

As described hereinabove, according to the present invention, the exposed surface of interconnects of a semiconductor device is protected with a protective film composed of a multi-layer laminated film. By making the laminated film of a laminate of a plurality of layers having various physical properties or performing various protective functions, e.g., a laminate of an oxidation-preventing layer for preventing oxidation of the interconnects and a thermal diffusion-preventing layer for preventing thermal diffusion of the interconnects, both of the oxidation and the thermal diffusion of the interconnects can be effectively prevented.

Although certain preferred embodiments of the present invention have been shown and described in detail, it should be understood that various changes and modifications may be made therein without departing from the scope of the appended claims.

Industrial Applicability This invention relates to a semiconductor device having an embedded interconnect structure in which an electric conductor, such as copper or silver, is embedded in fine recesses for interconnects formed in the surface of a semiconductor substrate, and having a protective film formed on the surface of the interconnects to protect the interconnects, and to a method for manufacturing such a semiconductor device.

1. A semiconductor device, comprising:
a semiconductor substrate having an interconnect structure in a surface of the semiconductor substrate;
an embedded interconnect embedded in the interconnect structure and having an exposed surface;
a first protective layer formed selectively on the exposed surface of the interconnect; and
a second protective layer formed on a surface of the first protective layer,
wherein a material of the second protective layer being different from a material of the first protective layer.

2. The semiconductor device according to claim 1, wherein said first protective layer is a thermal diffusion-preventing layer for preventing thermal diffusion of the interconnect, and said second protective layer is an oxidation-preventing layer for preventing oxidation of the interconnect.

3. The semiconductor device according to claim 2, wherein said oxidation-preventing layer is laminated on a surface of the thermal diffusion-preventing layer.

4. The semiconductor device according to claim 2, wherein said thermal diffusion-preventing layer comprises a Co or Co alloy layer, and said oxidation-preventing layer comprises a Ni or Ni alloy layer.

5. A method for manufacturing a semiconductor device, comprising:
providing a semiconductor substrate having an interconnect structure in a surface of the semiconductor substrate;
filling the interconnect structure with an electric conductor to form an embedded interconnect having an exposed surface;
forming a first protective layer selectively on the exposed surface of the interconnect; and
forming a second protective layer on a surface of the first protective layer,
wherein a material of the second protective layer is different from a material of the first protective layer.

6. The method according to claim 5, wherein said first protective layer comprises a thermal diffusion-preventing layer composed of a Co or Co alloy layer.

7. The method according to claim 5, wherein said second protective layer comprises an oxidation-preventing layer composed of a Ni or Ni alloy layer.

8. A method for manufacturing a semiconductor device, comprising:
providing a semiconductor substrate having in its surface a recess for interconnect;
embedding an electric conductor into the recess of a surface of the substrate;
flattening a surface of the substrate by chemical mechanical polishing, thereby forming an embedded interconnect having an exposed surface;
forming a first protective layer selectively on the exposed surface of the interconnect by electroless plating; and
forming a second protective layer selectively on a surface of the first protective layer by electroless plating.

9. The method according to claim 8, wherein said first protective layer comprises a thermal diffusion-preventing layer composed of a Co or Co alloy layer.

10. The method according to claim 8, wherein said second protective layer comprises an oxidation-preventing layer composed of a Ni or Ni alloy layer.

11. An apparatus for manufacturing a semiconductor device, comprising:
a first electroless plating device for forming a first protective layer selectively on a exposed surface of an embedded interconnect formed in a semiconductor substrate; and
a second electroless plating device for forming a second protective layer selectively on a surface of the first layer.

12. The apparatus according to claim 11, wherein said first protective layer comprises a thermal diffusion-preventing layer composed of a Co or Co alloy layer.

13. The apparatus according to claim 11, wherein said second protective layer comprises an oxidation-preventing layer composed of a Ni or Ni alloy layer.

14. The semiconductor device according to claim 3, wherein said thermal diffusion-preventing layer comprises a Co or Co alloy layer, and said oxidation-preventing layer comprises a Ni or Ni alloy layer.
